(19) United States
(12) Patent Application Publication
(10) Pub. No.: US 2009/0031659 A1
(43) Pub. Date: Feb. 5, 2009

(54) Evacuated Thermal Insulation Panel

(76) Inventor: Rami Abraham Kalfon, Kfar-Shmuel (IL)

Correspondence Address: EDWARDS ANGELL PALMER & DODGE LLP, P.O. BOX 55874, BOSTON, MA, 02205, US

(21) Appl. No.: 11/814,513

(22) PCT Filed: Jan. 24, 2006
(86) PCT No.: PCT/IL2006/000094

§ 371 Date: Apr. 2, 2008

Related U.S. Application Data
(60) Provisional application No. 60/645,967, filed on Jan. 24, 2005.

(51) Int. Cl. B32B 3/12

(52) U.S. Cl. 52/404.1; 52/741.4; 403/24; 137/511

(57) ABSTRACT

A sealed vacuum thermal insulation panel having a thermal barrier that comprises a core made of thermal insulation material and two panel walls made of a barrier material substantially impermeable to atmospheric gases and water vapors. The two panel walls covers opposite sides of the core. The sealed panel further comprises at least one lateral strip of substantially impermeable to atmospheric gases and water vapor. The lateral strip is adapted to sealably enfold the edges of the obverse side of the two panel walls. Additionally, the sealed panel further comprises at least one sealing strip, each comprising sealing material. The sealing strip is adapted to sealably join the edges to the inner side of the lateral strip.

### FIELD AND BACKGROUND OF THE INVENTION

The present invention relates to vacuum thermal insulation panels and to methods to manufacture them, and more particular but not exclusively to a vacuum thermal insulation panel with low conductivity and utilities for maintaining the predetermined pressure level for long periods and a method for bonding panels to insulation unit walls.

Effective thermal insulation is required in a wide range of areas. For example, thermal insulation is a necessity in the transportation of refrigerated products refrigerated containers and spaces, in transportation boxes, in refrigerators and freezers, in cold storage rooms, in refrigerated transport vehicles, buildings, and hot water storage units.

The thermal insulation is a barrier that minimizes the transfer of heat from the outer surrounding to an insulated space and vise versa, by reducing the conduction, the convection and the radiation effects. Hence, the thermal insulation level of any insulation unit is of great importance, in particular, because the energy requirements to maintain the temperature in insulation units can be significantly reduced by insulating those units with effective thermal insulation. In addition, better thermal conductivity can reduce the required width of the insulation walls since the thinner improved insulation panels achieves the same insulation level of regular insulation panels. Thermal insulation walls which are commonly used in insulation units is made from a wide range of thermal heat insulation products. For example, closed cell foams such as Polyuerthane foam, Polystyrene based foam, powder or mineral or glass fibers are commonly used. In addition, a few more known cores, though not commonly used, are for example powder cores or fibers cores which based upon, inter alia, glass fibers.

The aforementioned thermal insulation materials have relatively low thermal conductivity. For example, a core of rigid plastic foam has low thermal conductivity, approximately in between 0.02 W·m⁻¹·K⁻¹ and 0.05 W·m⁻¹·K⁻¹.

The thermal resistance of an insulation material depends on many factors, inter alia, the foam material, the blowing agent, moisture content, density, cell structure and size, composition of the cellular gas, and temperature at which the foam is used, presence of Opacifiers etc.

Vacuum insulation panels constitute an additional improvement of the traditional thermal insulation panels.

In order to decrease the thermal conductivity of the thermal insulation core, the core should be sealed in a space evacuated from atmospheric gases and water vapors.

Vacuum insulation panels comprise a core of insulation material enveloped in envelope material substantially impermeable to atmospheric gases and water vapors. The panel is evacuated to a predetermined pressure according to material of the core.

Such panels offer greatly enhanced thermal resistance for the same or even reduced thicknesses of the similar materials.

Hence, using vacuum insulation panels in the insulation of containers, rooms and other spaces allows their overall external size to be reduced, internal size increased or allows an increase in the container's thermal performance.

For example, when a core of rigid plastic foam is wrapped in a gas-tight film, evacuated to a pressure significantly lower than atmospheric pressure, its thermal conductivity decreases to lie within an approximate range of 0.001 W·m⁻¹·K⁻¹ and 0.009 W·m⁻¹·K⁻¹.

Accordingly, the state of the art suggests that in the case of single-use and multiple-use thermally insulated containers, vacuum insulation panels are used.

For example, there are panels that consist of a core of rigid plastic foam which is wrapped in a gas-tight film evacuated to a pressure significantly lower than atmospheric pressure. By sucking the air out of the pores, substantial low thermal conductivity value is achieved.

Hence, besides the choice of an insulation material with the best possible insulating properties, an important factor in the creation and the maintenance of the pressure level within the insulation panel is the choice of gas tight film.

Such a gas tight film should be inexpensive, preferably having a lowest possible heat transfer coefficient, and, as far as possible, be substantially impermeable to atmospheric gases and to water and water vapors, so that a predetermined pressure level can be kept within such an insulation panel for as long a period as possible.

In practice, the pressure level of the state of the prior art insulating vacuum panels increases over time, mainly due to penetration of atmospheric gases and water vapor through seams in the panel envelope. Accordingly, the thermal insulation provided thereby decreases over time.

A known solution to this problem is to add atmospheric gas absorbents and water vapor absorbents. The absorbents are chemical agents which are inserted into the panel's internal space before it is sealed and evacuated. The chemical agents absorb both the residual gasses and the gases that inevitably leak through the sealed panel envelope over time. The chemical agents trap the free atmospheric gases and water vapor molecules that have managed to penetrate into the internal space of the panel. Hence, the predetermined pressure level is maintained for a finite period.

However, the addition of chemical agents increases the production costs Moreover, the chemical agents have a finite effective duration and a finite absorption and adsorption capacity, hence limiting the effective life of a panel based on them.

Another known solution is to use a thermal insulation material with substantially small pores, such as Fume Silica or Aerogel. Such materials have the ability to maintain a substantially low thermal conductivity level over a wide range of pressure levels. For example, such a material sealed in a pressure of less than 100 millibars will maintain practically the same substantially low thermal conductivity as other foam sealed in a pressure of less than 0.9 millibars.

Thus, if Fumed Silica core materials are sealed in an evacuated panel, the increase in the pressure level in panels will have a relatively minor effect on their low thermal conductivity level, especially in the light of open cell polystyrene foam with typical cell size of 30 microns on average.

However, currently, Fumed Silica materials are relatively expensive, and lack the hardness benefits of other core materials such as Open Cell Foams, which can be used as a rigid skeleton for the structure of insulation panels.

In some configurations, the films which are used to form walls of insulation panels are metallic.

Due to production costs concerns, generally Aluminum films are used. Since Aluminum films have relatively high heat conductivity, the heat can be conducted from one side of the panel via the lateral surface of the panel, to the other side of the panel thereby bypassing the insulation effect of the enveloped core material. Clearly, this conduction, which is also known as thermal edge or thermal bridge, can substantially reduce the insulation performance of a panel.

There is a requirement to provide a gas tight film or a laminate with lower thermal conductivity than Aluminum in order to reduce the amount of heat being transferred across the skin of the panels. In order to maintain the pressure within the panel, a thermal barrier has to be coupled to the films. Moreover, the material of the thermal barrier has to be chosen as an optimum between sealing ability, impermeability to gas and impermeability to water vapors. Whatever material is chosen there is some permeability of either gas or water vapors. Hence, there are disadvantages in the prior art and it would be highly advantageous to have, a thermal insulation panel which both retains the pressure level within the insulation panel and functions as an effective thermal barrier about its skin.

In International Patent Application No. WO 98/29309, issued on Sep. 7, 1998, a vacuum insulation panel is disclosed that uses a bag as a casing for insulation core. The bag has a tubular portion for integral evacuation. In the process of creating of the panel, the panel's internal space is filled with thermally insulating foam of rigid plastic micro-porous material and then evacuated using a vacuum suction source. Though the rigid plastic micro-porous sealed-in evacuated container provides a good insulation layer, the WO 98/29309 vacuum insulation panels fails to maximize the utility of the insulation potential of the panel. This failure is an outcome of high thermal conductivity of the outer casing's material which is usually made of films with high thermal conductivity, for example aluminum films and metallized films.

Though films with relatively lower conductivity can solve the conductivity problem, such a use is either expensive or not appropriate from other reasons such as instability, fragility or low warmth durability etc.

Another vacuum insulation panel is disclosed in U.S. Pat. No. 6,863,949, issued on Mar. 8, 2005. The disclosed panel is a film-enveloped evacuated thermal insulation panel.

The U.S. Pat. No. 6,863,949 patent discloses a stable thermal insulation core, pre-formed from a porous material, which is enveloped in a gas-tight single cut film 2 which has been evacuated to create vacuum. In this teaching, as in the previous WO 98/29309 invention, the main problem addressed is the high conductivity of the panel's envelope. The used film uniformly envelops the insulation material core without integrating any thermal barriers to reduce its conductivity potential. Therefore, the vacuum insulation panel according to WO 98/29309 can conduct heat from one side to the opposite side. Hence, in order to reduce the conductivity of the panel the film may be made from relatively nonconductive film materials, which are either expensive or less impermeable to atmospheric gases than Aluminum.

Another solution to the conductivity problem is to replace the traditional insulation panels that are made from one layer of metal film with panels comprising a seal made of flexible laminate containing several layers of polymers or coated with polymers. The use of nonmetal or metallized materials can decrease the thermal conductivity and the thermal edge effect.

Laminated films that comprise various types of coated and uncoated polymers and metal foils and the combination thereof, which are convenient to make pouches from, do not completely solve the gas permeation problem. Though not conductive, seams in the sealing still are partly exposed to the outer environment.

Thus, it can be highly beneficial to have a sealing layer that is relatively gas tight, in order to reduce gas penetration rate of molecules through the seams.

Standard Atmospheric Pressure is 1013.25 mb and the panel's internal pressure level is around 0.01 mb to 100 mb so the seam must have low permeability to gases in order to maintain the pressure difference and in essence maintain the vacuum. A gas leak from the seam decreases the vacuum level over time, raising the thermal conductivity level of the panel.

As mentioned above, one disadvantage of the state of the art is the difficulty to economically maintain the vacuum for long periods.

In order to solve the increasing pressure problem, different approaches have been tested and practiced. For example the prior are discloses the insertion of water and water vapors absorbents like desiccant agents and the insertion of atmospheric gas absorbents such as getters into the sealed evacuated panel. However, the absorbents provide only a partial solution since the absorbents are inserted before the panel is sealed or evacuated. Hence, some of the getters and the desiccants absorb moisture and air even before the designated pressure level, by pumping, was achieved, and thus use up valuable capacity. Moreover, since the panel is sealed after insertion, there is no practical way to replace the absorbents, unless re-pumping is performed.

It should be mentioned that the state of the art panels do not currently include any efficient mechanism that facilitates re-evacuation of the insulation panels, either by a pump, or by replacing the atmospheric gas absorbents and water vapors absorbents within the panel.

Predetermined pressure levels within the panel can be maintained by periodically re-evacuating or by doing so when the pressure decreases. The measurement of pressure level in sealed containers is utilized in many diverse applications, and many different types of pressure measuring devices have been developed for each particular application. One class of pressure level detectors, is based on the measurement of changes in thermal conductivity accompanying changes in pressure, and thereby changes in density, of the gas.

However, the state of the art does not disclose a panel that can indicate to the layman the pressure level in the insulation panel at any given moment, to facilitate timely re-evacuation of the panel accordingly. A known solution is a mechanism that measures the thermal conductivity of the surface of vacuum insulated panel.

However, since the aforementioned mechanism is exposed to the outer surrounding temperature and humidity it is not sufficiently precise.

Another known problem in the prior art is related to the positioning of the insulation panel within insulation units. In order to achieve good insulating for the insulation unit, the internal surface of the insulation unit is coated with insulation panels.

Evacuated insulation panels are usually placed in between external and internal walls of the insulation units.

The evacuated panels are usually positioned in the proximity of the internal or external side of the external wall, leaving a gap between the insulation panel and the external wall. Later, a liquidate polyurethane is injected into the aforementioned gap thereby sealing the gap and coupling the insulation panel to the external wall. Hence, the polyurethane fixes the panel to its place. The same procedure is usually done to couple the internal walls of the insulation unit to the insulation panel.

This procedure adds layers of cured polyurethane to the overall width of the insulation unit wall. In many situations such a procedure is not feasible, as the overall dimensions are restricted and so increased insulation thickness reduces the usable volume and thus the functionality.

The layer of cured polyurethane is relatively voluminous and reduces the relative effective cooling storage space by increasing the thickness of the walls.

Hence, a method that will allow the adhesion of vacuum insulation panels to the insulation unit casing and the partition walls without substantially increasing the thickness of the insulation units' walls is needed.

The panel walls thickness is an important consideration in designing and manufacturing insulation units. The advantage in such thermal insulation elements is clear.

Thus, there is a widely recognized need, not satisfied by the prior art, for a thermal insulation panels and for a method to produce it, and it would be highly advantageous to have, a thermal insulation panels devoid of the above mentioned limitations.

### SUMMARY OF THE INVENTION

According to one aspect of the present invention there is provided A sealed panel for vacuum thermal insulation, the panel having a thermal barrier, the panel comprising: a core made of thermal insulation material; a first and a second panel wall, each made of a first barrier material substantially impermeable to atmospheric gases and water vapor, the first and second panel walls respectively having an obverse and a reverse sides, the reverse sides respectively covering opposite sides of the core; at least one lateral strip comprising a second barrier material substantially impermeable to atmospheric gases and water vapor, the lateral strip having an internal and an external side, the lateral strip being adapted to sealably enfold the edges of the obverse side of the first and second panel walls; and at least one first sealing strip comprising sealing material, the first sealing strip adapted to sealably join the edges to the internal side of the lateral strip.

According to one preferred embodiments of the present invention the first sealing strip is laminated on the obverse sides of side first and second panel walls respectively.

Preferably the sealed panel further comprising a second sealing strip, the second sealing strip being laminated on the internal side of the lateral strip.

Preferably the thermal conductivity of the second barrier material is lower then the thermal conductivity of the first barrier material.

More preferably one of or both the obverse of the first and second panel walls and the external side of the lateral strip further comprises a coating layer having a relatively lower thermal conductivity than Aluminum.

Preferably, the sealed panel further comprising at least one desiccating agent or getters located in-between the first and second panel walls.

Preferably the first sealing material consists of at least one of the following sealing materials: a rubber-modified acrylonitrile copolymer, a thermoplastic resin (PVC), Liquid Crystal Polymers (LCP), Polyethylene teraphtalate (PET), Polyvinylidene Chloride (PVDC), and Polyvinylidene Chloride mixed with Polychlorotrifluoroethylene (PCTFE).

More preferably, the core consists of at least one of the following materials: pyrogenic silicic acid, polystyrene, polyurethane, glass fibers, perlite, open cell organic foam, precipitated silica, and fumed silica.

More preferably, the first sealing material is blended with nano-composites of clay or with flame-retardants.

More preferably, the lateral strip comprises an alloy consisting of at least one of the following materials: Titanium, iron, nickel, cobalt, and stainless steel.

More preferably, the first sealing strip is a dual layer strip comprising:

an internal layer of one of a first material substantially impermeable to atmospheric gases and a second material substantially impermeable to water and water vapor; and an external layer of the other of the first material and the second material, wherein the external layer sealably covers the internal layer.

Preferably, the first material is rubber-modified acrylonitrile copolymer; wherein the second material is polyethylene.

Preferably, the first barrier material consists of at least one of the following materials: non ferrous metal and Alloy comprising at least one non ferrous metal.

Preferably, one or both the first and a second panel walls and the lateral strip are a laminate, wherein the laminate consists at least one of one layer of the following layering materials: Polyethylene teraphtalate (PET), Polyethylene Naphthalate (PEN), Cyclic Olefin Copolymer (COC), Liquid Crystal Polymers (LCP), Polyvinylidene Chloride (PVDC), and barrier adhesive like PVDC.

According to another aspect of the present invention there is provided a sealed panel for evacuated thermal insulation, comprising: a first sealing strip comprising a first sealing material being characterized by a first predetermined impermeability to gases and by a second predetermined impermeability to water vapors, wherein the first predetermined impermeability is higher than the impermeability to gases of High-Density Polyethylene and the second predetermined impermeability is lower than the impermeability to water vapors of High-Density Polyethylene; and at least one desiccating agent.

Preferably, the first sealing material is rubber-modified acrylonitrile copolymer.

Preferably, the sealed panel further comprising: a core made of thermal insulation material and a first and a second panel wall respectively made of a first barrier material substantially impermeable to atmospheric gases and water vapors, the first and second panel walls having obverse and a reverse sides respectively, wherein the reverse sides of the first and second panel walls respectively cover opposite sides of the core; wherein the first sealing strip being positioned to sealably join the edges of the reverse sides of the first and a second panel walls.

According to another aspect of the present invention there is provided a method of producing sealed vacuum thermal insulation panels, comprising the following steps: a) providing a core of thermal insulation material; b) providing a first and a second panel wall of a first material substantially impermeable to gas and water vapor, the first and a second panel having an obverse and a reverse sides; c) positioning the reverse sides of the first and second panel walls to respectively cover opposite sides of the core; d) providing at least one lateral strip of a second material substantially impermeable to gas and water vapor, the lateral strip having an external and a internal side; e) laminating the obverse sides of the first and second panel walls with a first coating layer of a sealing material; and f) sealably enfolding the edges of the obverse sides of the first and second panel walls using the internal side of the lateral strip.

Preferably, the method further comprising a step between step “b” and “c” of laminating the reverse sides of the first and second panel walls with an adhesive layer of an adhesive material.

More preferably, the method further comprising a step between step “d” and “e” of laminating the internal side of the lateral strip with a second coating layer of the sealing material.

More preferably, step f) of the method further comprises leaving an unsealed aperture between the edges of the obverse sides of the first and second panel walls and the lateral strip; further comprises the following step: g) connecting a suction source to the aperture; h) evacuating atmospheric gases, water and water vapors via the aperture; and i) sealing the aperture.

According to another aspect of the present invention there is provided an evacuated insulation panel with an instrument for maintaining a predetermined pressure level thereof, comprising: a sealed insulation panel comprising a film of material substantially impermeable to atmospheric gases and water vapor; an evacuation orifice provided in the sealed insulation panel; an instrument for maintaining predetermined pressure level, the instrument comprising: a vacuum valve having a valve stopper positioned to overlie the evacuation orifice, being positioned partly within the sealed insulation panel, partly on the outer surface of the sealed insulation panel, the valve default status being closed, a suction interface located in the proximity of the valve stopper, the suction interface adapted to be connected to a source of vacuum suction.

Preferably, the suction interface being further adapted to be connected to an adaptor of the source of vacuum suction.

More preferably, the evacuated insulation panel further comprising a spout substantially forming a valve tube with an open first end and an open second end, wherein the vacuum valve being positioned within the valve tube, the spout overlies the evacuation orifice.

More preferably, the spout is made of material substantially impermeable to atmospheric gases.

More preferably, the vacuum valve comprises: a sink shaped chamber having at least one aperture and a valve stopper; a spring recess located in the sink shaped chamber; a spring adapted to be threaded on the recess, pressing the valve stopper toward the evacuation orifice, the spring being adapted to maintain the vacuum valve closed when released or open when pressed by the valve stopper.

Preferably, the vacuum valve further comprises a vacuum valve plug, the vacuum valve plug being adapted to be removably connected to the valve stopper; the vacuum valve plug being adapted to prevent the valve stopper movement when plugged.

More preferably, the evacuated insulation panel of claim 43, further comprising a linking fitting adapted to be connected to the vacuum valve via the suction interface, the linking fitting being adapted to transfer suction pressure between the vacuum valve and a suction apparatus or an adaptor thereof, the linking fitting having an integrated tube operable for facilitating access to the valve stopper.

More preferably, the evacuated insulation panel further comprising: a pressure indicator being positioned within the sealed insulation panel; and a plug positioned on the external side of the sealed insulation panel, connected to the pressure indicator through an orifice in the sealed insulation panel, operative for receiving information regarding the pressure level within the sealed insulation panel via the connection.

More preferably, the evacuated insulation panel further comprising: an electrical resistor having a resistance varying with temperature to be positioned within the sealed insulation panel; a power supply for supplying the electrical resistor with electrical current to heat it to a predetermined temperature above the temperature of the inner space of the sealed insulation panel, the power supply is connected to the electrical resistor through an orifice in the sealed insulation panel; and a processor for measuring changes in resistance of the electrical resistor is used to produce a measurement of the rate of thermal heat dissipation of inner space of the sealed insulation panel, and thereby a measurement of the pressure level within the sealed insulation panel, the heat processor is positioned o the outside of the sealed insulation panel, wired to the electrical resistor through the evacuation orifice.

More preferably, the electric resistor is a thermistor.

More preferably, the evacuated insulation panel further comprising: an induction heating element for generating heat through electromagnetic induction by the action of magnetic flux generated by a magnetic flux generator adapted to be positioned in the proximity of the insulation panel, the induction heating element being adapted to be positioned within the sealed panel; wherein the pressure indicator is a temperature detection element for operable to produce a measurement of the rate of thermal heat dissipation of inner space of the sealed insulation panel, and thereby a measurement of the pressure level within the sealed insulation panel.

More preferably, the pressure indicator comprises: a vacuum sealed capsule of a bending membrane enclosing a spring supporting the walls of the vacuum sealed capsule in a manner that the bending of the sealed capsule affects the spring degree of compression; and a compression evaluator operable for measuring the spring compression to produce a measurement of the vacuum sealed capsule curvature, and thereby a measurement of the pressure level of the sealed insulation panel, the compression evaluator operative for transmitting the information to the plug according to the measurement.

More preferably, the pressure indicator comprises: a vacuum sealed capsule of a bending membrane; a laser-based distance detector located in the proximity of the vacuum sealed capsule, operable for measuring the distance between the laser-based distance detector and the bending membrane to produce a measurement of the vacuum sealed capsule curvature, and thereby a measurement of the pressure of the sealed insulation panel, the pressure indicator operative for transmitting the information to the plug according to the measurement; and a power supply for supplying the laser-based distance detector with electrical current, connected to the laser-based distance detector through an aperture in the panel sealing.

More preferably, the pressure indicator comprises: a piezoelectric device being positioned within the sealed insulation panel, operable for measuring the mechanical pressure on the piezoelectric device to produce a measurement of a pressure level, and thereby to turn the mechanical pressure into a voltage representing the pressure level, the pressure indicator transmit the information according to the voltage; a power supply for supplying the piezoelectric pressure sensing device with electrical current, connected to the piezoelectric pressure sensing device through the evacuation orifice. According to another aspect of the present invention there is provided a vacuum valve for maintaining predetermined pressure levels in sealed insulation panels, comprising: a sink shaped chamber adapted to overlie an evacuation aperture in sealed insulation panels, sink shaped chamber having an evacuation orifice, a valve stopper adapted to overlie the evacuation orifice, the valve stopper being adapted to be positioned on the outer surface of the sealed insulation panels, the valve stopper default status being closed; and a suction interface located in the proximity of the evacuation orifice, the suction interface being adapted to be connected to a source of vacuum suction.

Preferably, the suction interface being further adapted to be connected to an adaptor of the source of vacuum suction.

According to another aspect of the present invention there is provided a method of producing sealed vacuum thermal insulation panels having a vacuum valve, comprising the following steps: a) providing a sealed insulation panel of film substantially impermeable to atmospheric gases and water vapor, the panel having an aperture; b) providing a permanent vacuum valve having a valve stopper, the permanent vacuum valve adapted to overlie the aperture, the permanent vacuum valve having a suction interface, the suction interface adapted to be connected to a source of vacuum suction; c) positioning the permanent vacuum valve in the aperture; d) connecting a source of vacuum suction to the suction interface; and e) evacuating the sealed insulation panel using the source of vacuum suction.

According to another aspect of the present invention there is provided a vacuum pump adaptor for suction transfer between permanent vacuum valves of sealed insulation panels and suction apparatus, comprising: a readily removable pedestal having a bottom duct for sealably connecting a permanent vacuum valve and a top outlet for sealably connecting a suction apparatus; a pivot screwed through the readily removable pedestal, having a rotating handle operable for facilitating the screwing or the unscrewing of the pivot, the pivot being operable for retaining the vacuum valve open during the suction transfer.

According to another aspect of the present invention there is provided a replacement device for replacing getters and desiccating agents in a vacuum sealed panel, comprising: a sink shaped chamber adapted to be positioned to overlie an aperture in the sealing of the vacuum sealed panel, having at least one gas-permeable wall and an aperture, the sink shaped chamber being operative for holding getters and desiccating agents; and a cover of material substantially impermeable to atmospheric gases and water vapor, the cover designed to sealably overlie the aperture, being proximately positioned at the external side of the vacuum sealed panel.

Preferably, the cover is a removable cover. Preferably, the cover is a permanent cover.

More preferably, wherein the sink shaped chamber further comprises: a suction interface provided in the sink shaped chamber, the suction interface one end connection that matches the aperture and another end connection that matches a source of vacuum suction.

Preferably, the sink shaped chamber further comprises an O-ring positioned in a groove in the internal walls of the sink shaped chamber, the O-ring being adapted to seal the junction between the sink shaped chamber and the cover.

According to another aspect of the present invention there is provided a method of producing sealed vacuum thermal insulation panels having a housing for getters and desiccating agents, comprising the following steps: a) providing a sealed insulation panel of film substantially impermeable to atmospheric gases and water vapors, the panel having an aperture and a vacuum valve; b) providing a replacement device overlaying the aperture, the replacement device comprises a sink shaped chamber with at least one gas-preamble wall and a cover being substantially impermeable to atmospheric gases and water vapor, arranged to overlie the orifice of the sink shaped chamber; c) positioning the replacement device in the aperture; d) connecting the vacuum valve to a source of vacuum suction; e) evacuating the sealed insulation panel using the source of vacuum suction; f) inserting at least one absorbent agent to the sink shaped chamber; and g) closing the aperture using the cover.

According to another aspect of the present invention there is provided a method for coupling partition films to insulation panels in insulation units, comprising the following steps: a) providing at least one thermal insulation panel having an obverse side and a reverse side and at least one partition film; b) laminating a first layer of thermally activated adhesive on the obverse side of the thermal insulation panel; c) coupling the reverse side of the thermal insulation panel to the inner side wall of a insulation unit;

d) sealably positioning the partition at the proximity of the thermal insulation panel at room temperature; e) transmitting an activation radiation on the resultant arrangement of the positioning to thereby activate the first layer of thermally activated adhesive, gluing the obverse the of the thermal insulation panel with the partition film.

According to another aspect of the present invention there is provided a vacuum thermal isolating panel, comprising a thermal isolating porous material packed in a sealed bag, the bag having a plurality of substantially impermeable metallic films being welded via a sealing layer, wherein the plurality of metallic films are arranged such as to have oxygen transmission rate of less than 0.005 (cc mM/m² day ATM) at 55 degrees centigrade.

According to another aspect of the present invention there is provided a vacuum thermal isolating panel, comprising a thermal isolating porous material packed in a sealed bag, the bag having at least one substantially impermeable film having therein at least one metallic layer other than aluminum.

According to another aspect of the present invention there is provided a vacuum thermal isolating panel, comprising a thermal isolating porous material packed in a sealed bag, the bag having at least one substantially impermeable metallized film having at least one layer of Polyethylene Naphthalate therein.

According to another aspect of the present invention there is provided a vacuum thermal isolating panel, comprising a thermal isolating porous material packed in a sealed bag the bag having at least one substantially impermeable metallized film having at least one layer of polyvinyl alcohol therein.

According to another aspect of the present invention there is provided a vacuum thermal isolating panel, comprising a thermal isolating porous material packed in a sealed bag, the bag having at least one substantially impermeable metallized film having at least one layer of cycloolefin copolymer therein.

Unless otherwise defined, all technical and scientific terms used herein have the same meaning as commonly understood by one of ordinary skill in the art to which this invention belongs. The materials, methods, and examples provided herein are illustrative only and not intended to be limiting.

Implementation of the method and system of the present invention involves performing or completing certain selected tasks or steps manually, automatically, or a combination thereof. Moreover, according to actual instrumentation and equipment of preferred embodiments of the method and system of the present invention, several selected steps could be implemented by hardware or by software on any operating system of any firmware or a combination thereof.

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of the preferred embodiments of the present invention only, and are presented in order to provide what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

In the drawings:

FIG. 1A is an exemplary, sealed panel for vacuum thermal insulation according to an embodiment of the present invention.

FIG. 1B is an exemplary, sealed panel for vacuum thermal insulation with a laminated sealing strip according to an embodiment of the present invention.

FIG. 2 is another exemplary, sealed panel for vacuum thermal insulation further comprising getters and desiccating agents, according to an embodiment of the present invention.

FIG. 3A is another exemplary, sealed panel for vacuum thermal insulation comprising dual layer of a sealing strip, according to a preferred embodiment of present invention.

FIG. 3B is an exemplary, sealed panel for vacuum thermal insulation with a thermal barrier according to an embodiment of the present invention.

FIG. 4 is a simplified flowchart diagram of a method for manufacturing a welded vacuum thermal insulation panel, according to a preferred embodiment of present invention.

FIG. 5A is another simplified flowchart diagram of a method for manufacturing a welded vacuum thermal insulation panel, according to a preferred embodiment of present invention further comprises evacuation and hermetic sealing steps.

FIG. 5B is another simplified flowchart diagram of a method for manufacturing a welded vacuum thermal insulation panel, according to a preferred embodiment of present invention and providing the ability to supplement desiccating agent.

FIG. 6 is a comparative graph that depicts the oxygen transmission rate and water vapor transmission rate of selected polymer materials.

FIG. 7 is a comparative graph that depicts the effect of the Aluminum foil layer thickness in the vacuum insulated panel's envelope on the conductivity of vacuum insulated panels at various sizes.

FIG. 8 is an exemplary, sealed panel for vacuum thermal insulation with a fixed vacuum valve according to an embodiment of the present invention.

FIG. 9 is an exemplary, permanent valve that allows initial pumping and pumping for maintenance predetermined pressure level, according to a preferred embodiment of the present invention.

FIG. 10A is an external perspective view of a spout enveloping a vacuum valve, according to a preferred embodiment of the present invention.

FIG. 10B is another external perspective view of the spout of FIG. 10A, according to a preferred embodiment of the present invention.

FIG. 11 is an exemplary, illustrative permanent vacuum valve connected to a vacuum valve pump adaptor, according to a preferred embodiment of the present invention.

FIG. 12A is an external perspective view of an adaptor connected to a spout, according to a preferred embodiment of the present invention.

FIG. 12B is another external perspective view of the adaptor and spout of FIG. 12A, according to a preferred embodiment of the present invention.

FIG. 13 is another exemplary, permanent vacuum valve connected to a vacuum valve pump adaptor further comprising a linking fitting, where the pumping is done by access through an intermediated layer of foam between the wall and the vacuum panel according to a preferred embodiment of the present invention.

FIG. 14A is another exemplary, permanent vacuum valve connected to a linking fitting, according to a preferred embodiment of the present invention.

FIG. 14B is a flowchart of an exemplary method for producing an insulation panel with a vacuum valve according to a preferred embodiment of the present invention.

FIG. 15 is an exemplary, valve plug for sealing vacuum valve apertures according to an embodiment of the present invention.

FIG. 16A is an exemplary, sealed thermal insulation panel with a permanent vacuum valve for maintaining the predetermined pressure level within the panel and a pressure indicator according to an embodiment of the present invention.

FIG. 16B is another exemplary, illustrative sealed thermal insulation panel with permanent vacuum valve and an electric resistor as a pressure indicator, according to an embodiment of the present invention.

FIG. 17 is another exemplary, illustrative sealed thermal insulation panel with permanent vacuum valve for maintaining the predetermined pressure level or pressure level range within the panel and a capsule of bending membrane as a pressure indicator according to an embodiment of the present invention.

FIG. 18 is an external perspective view of a pressure indicator plug positioned on the external side of a panel wall.

FIG. 19 is an exemplary, illustrative gas and water vapor absorbent replacement device in an evacuated sealed container with a pressure indicator, according to an embodiment of the present invention.

FIG. 20A is an intersection perspective view of the gas and water vapor absorbent replacement device positioned in a panel wall.

FIG. 20B is a close-up intersection perspective view of the junction between the valve's removable cover and the valve chamber's inner walls.

FIG. 20C is an external perspective view of the absorbents replacement device showing the top surface thereof.

FIG. 21 is a simplified flowchart diagram of a method for manufacturing a welded vacuum thermal insulation panel having an absorbents housing, according to a preferred embodiment of present invention.

FIG. 22 is a simplified flowchart diagram of a method for coupling partition films to insulation panels, according to a preferred embodiment of the present invention.

FIG. 23 is another simplified flowchart diagram of a method of coupling partition films to insulation panels, according to a preferred embodiment of the present invention, the method including panel maintenance steps.

FIG. 24 is an exemplary, insulation unit for refrigerated vehicles according to a preferred embodiment of the present invention.

FIG. 25 is another exemplary, insulation unit for refrigerated vehicles according to a preferred embodiment of the present invention.

FIG. 26 is an exemplary, sealed insulation unit that integrates a system that uses compressed Helium for cooling and heating according to a preferred embodiment of the present invention.

FIG. 27 is another exemplary, sealed insulation unit that integrates a system that uses compressed Helium for cooling and heating according to a preferred embodiment of the present invention.

### DESCRIPTION OF THE PREFERRED EMBODIMENTS

The present embodiments comprise a vacuum thermal insulation panel with low thermal conductivity and features for maintaining the predetermined pressure level range for long periods. In addition, the present embodiments comprise a method for manufacturing of vacuum thermal insulation panels and a method for coupling partition walls to insulation panels in insulation units.

The principles and operation of an apparatus and method according to the present invention may be better understood with reference to the drawings and accompanying description.

Before explaining at least one embodiment of the invention in detail, it is to be understood that the invention is not limited in its application to the details of construction and the arrangement of the components set forth in the following description or illustrated in the drawings. The invention is capable of other embodiments or of being practiced or carried out in various ways. Also, it is to be understood that the phraseology and terminology employed herein is for the purpose of description and should not be regarded as limiting.

The present embodiments relate to thermal evacuated insulation panels, methods of producing thermal insulation panels and walls that comprises insulation panels, and equipment for use to maintain predetermined pressure level within thermal insulation panels.

In one preferred embodiment of the present invention a vacuum sealed panel for thermal insulation is disclosed. The vacuum sealed panel is designed to insulate spaces such as mobile insulation units, cooling rooms, refrigerator, freezers, hot water storage tanks, building walls etc. The panel comprises a core made of thermal insulation material placed between two films of material substantially impermeable to atmospheric gases and water vapor.

In order to seal the panel lateral surface area, a lateral strip enfolds the edges of the external side of the films, and covers the gap between the films. A sealing strip is laminated in between the lateral strip and the edges of the external side of the films, sealably joining the films and the lateral strip. The unique structure of the present embodiments provides a panel with low thermal conductivity and high insulation level.

Another preferred embodiment of the present invention teaches the method for manufacturing such insulation panels.

In another preferred embodiment of the present invention another vacuum sealed panel is disclosed. In this embodiment, the sealed panel comprises a core made of thermal insulation material having two opposite sides, each covered with a film of material substantially impermeable to atmospheric gases and water vapors. The panel further comprises a sealing strip comprising a rubber-modified acrylonitrile copolymer.

Preferably, the sealing strip is laminated on the external side of the films.

Preferably, an additional sealing strip is laminated on the internal side of the lateral strip.

The sealing strip sealably joins the edges of the external side of the films. By doing so the sealing strip sealably covers the lateral surface area of the panel. However, since the sealing strip is made of rubber-modified acrylonitrile copolymer, it has a relatively higher rate of permeability to water and water vapor than the rate of rate of permeability to water and water vapor of high density polyethylene (HDPE). Hence, desiccating agents are also positioned in between the films before the sealing strip is positioned to absorb the penetrating water vapor from the outer surrounding through seams in the sealing into the internal space which was create between the films and the sealing strip.

A sealed panel according to this embodiment of the present invention has a relatively low permeability to atmospheric gases since the rubber-modified acrylonitrile copolymer is used as a gas barrier.

In another preferred embodiment of the present invention, unique panels that provide the ability to maintain the predetermined pressure level for long periods of time are disclosed. The panels according to the preferred embodiment are sealed insulation panels having an evacuation orifice covered with a permanent vacuum valve. The vacuum valve has a suction interface. The suction interface facilitates the connection of a source of vacuum suction to the vacuum valve thereby facilitating the re-evacuation of the attached insulation panel.

Another preferred embodiment of the present invention discloses panels that provide the ability not just to maintain the insulation panel but also to receive an indication regarding the pressure level within the panel.

In another preferred embodiment of the present invention an adaptor that facilitates the connection of various suction sources to vacuum valves of insulation panels is disclosed. Preferably, the adaptor facilitates access to vacuum valves of insulation panels which are located behind partition walls, without the need to remove the partition wall. In use, the adaptor creates a unique pressure environment around the valve, prior to the valve opening. Subsequently, the valve is opened, facilitating the suction of atmospheric gases and water vapors from the internal space of the panel. In this manner, the pressure inside the panel do not rise during the opening of the valve.

In another preferred embodiment of the present invention a method of producing sealed vacuum thermal insulation panels having a vacuum valve is disclosed. The first step is to provide a sealed insulation panel having a film substantially impermeable to atmospheric gases and water vapor, and further having an aperture and a permanent vacuum valve having a valve stopper. In the following step the vacuum valve is overlaid to cover the aperture in the sealing. In the following step a source of vacuum suction is connected to a suction interface within the vacuum valve. The connection facilitates the next step of evacuating the sealed insulation panel using the suction source to a predetermined level. Since the vacuum valve is coupled with a valve stopper with a default status of being closed, the disconnecting of the suction source does not impede the achieved predetermined vacuum level within the panel.

Such a vacuum valve integrated insulation panel is highly beneficial, since such a vacuum valve can be used both for evacuating and re-evacuating gases and water vapors from the internal space of the insulation panel.

In another preferred embodiment of the present invention, a gas and water vapor absorbing agent replacement device for a vacuum thermal insulation panel is disclosed. This embodiment facilitates the ability to, inter alia, maintain the predetermined pressure level within the insulation panel. The embodiment discloses a device that comprises a sink shaped chamber adapted to be positioned within an aperture in the external sealing of a vacuumed thermal insulation panel. The sink shaped chamber has a wall which is semi-permeable to gas and water vapor that facilitates relativity slow diffusion of atmospheric gases and water vapor between the sink shaped chamber and the internal space of the vacuum thermal insulation panel. The sink shaped chamber is shaped to contain getters. The chamber is covered in a gas tight manner with a removable cover that facilitates the replacement of overused gas and water vapor absorbents.

Getters, molecular sieves and desiccating agents have the ability to absorb molecules as or to react with molecules thereby transferring them from gaseous phase to solid phase. Hence, the insertion of new getters, gas absorbing agents and desiccating agents to the internal space of the insulation panel can assist in maintaining the pressure within the internal space of the panel.

Another preferred embodiment of the present invention teaches a method for manufacturing insulation panels with a valve for replacement of absorbent agents and desiccant agents.

Another preferred embodiment of the present invention discloses a method for coupling partition films to insulation panels in insulation units. This unique method uses thermally activated adhesive to closely attach partition films to insulation panels.

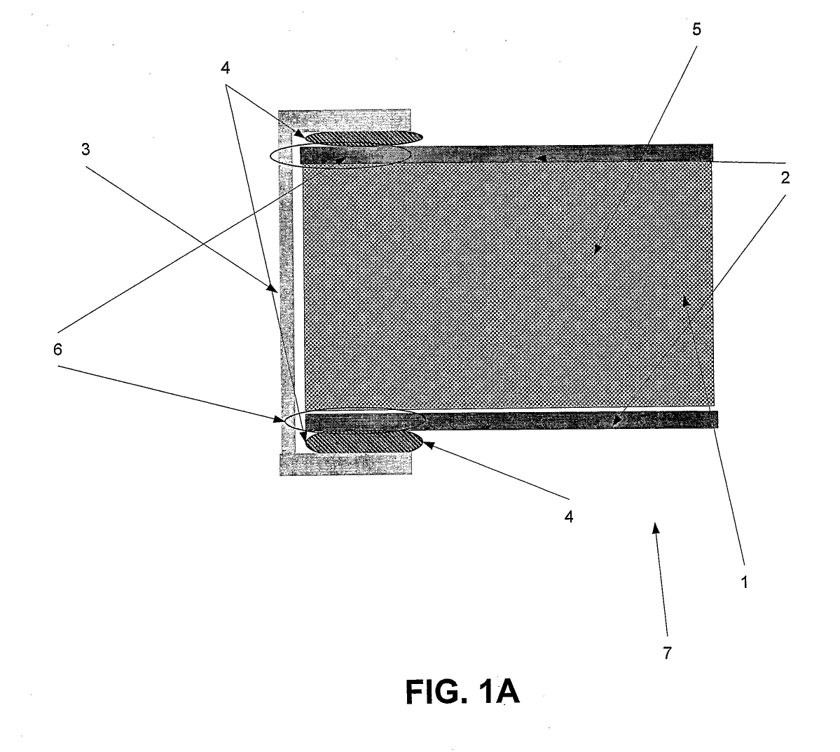

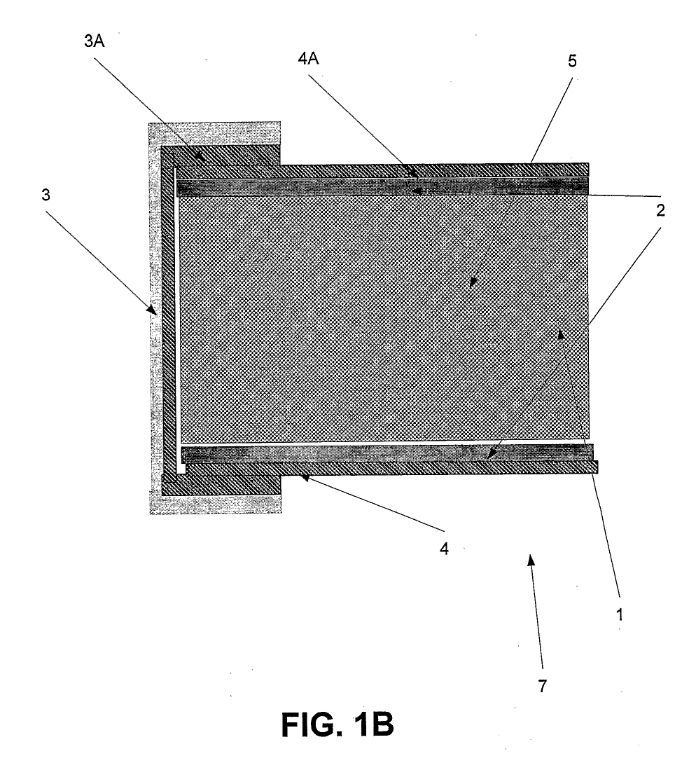

Reference is now made to FIG. 1A which depicts an exemplary, sealed panel for vacuum thermal insulation according to a preferred embodiment of the present invention. In FIG. 1, reference numeral 1 indicates a core of thermal insulation material, laid between two panel walls 2 of material substantially impermeable to atmospheric gases and water vapor. A lateral strip 3 sealably enfolds the panel walls 2. The gap between the edges of the external side of the panel walls 6 and the internal side of the lateral strip is sealed with a strip of sealing material 4. In particular, the unique vacuum sealed panel for thermal insulation is designed to insulate spaces designated for preserving predetermined temperature, for example, mobile insulation units, cooling room, etc. The core of thermal insulation material 1 is made of thermal insulation material. The thermal insulation material may be made of powders, pyrogenic silicic acid, polysrene, polyurethane, glass fibers, perlite, open cell organic foam, precipitated silica, or the combination thereof.

Preferably, the thermal insulation core 1 is made of rigid plastic microporous foam.

Thermal conductivity of the thermal insulation material increases when the concentration of water, water vapors and gases in its proximity is raised.

For Example, a core of rigid plastic foam has low thermal, approximately in between 0.02 W·m⁻¹·K⁻¹ and 0.05 W·m⁻¹·K⁻¹.

However, when the core of rigid plastic foam is wrapped in a gas-tight film and evacuated to a pressure significantly lower than atmospheric pressure, its thermal conductivity decreases to the approximate range of 0.001 W·m⁻¹·K⁻¹ and 0.009 W·m⁻¹·K⁻¹.

Moreover, there are known materials which were specifically developed for sealed and evacuated panels. For example, the Instill™ vacuum insulation core of the Dow Chemical Company has a thermal conductivity of 0.0048 W·m⁻¹·K⁻¹ at 0.1 millibar. The thermal conductivity of Instill™ substantially depends on the pressure of the surroundings.

Hence, in order to decrease the thermal conductivity of the thermal insulation core 1, the panel internal space 5 is designed to maintain a predetermined pressure level of less than 200 millibar.

Accordingly, two panel walls 2 of material substantially impermeable to atmospheric gases and water vapor are positioned to cover the opposite sides of the thermal insulation core 1, leaving the lateral surface area of the thermal insulation core uncovered.

Preferably, since the panel walls 2 cover most of the panel they are preferably made from relatively inexpensive materials, such as aluminum films, to avoid high manufacturing costs. In one preferred embodiment of the present invention, the films are made of Aluminum, which is substantially impermeable to atmospheric gases and to moisture, depending on thickness. Each Aluminum film is typically 6 micrometer thick or more.

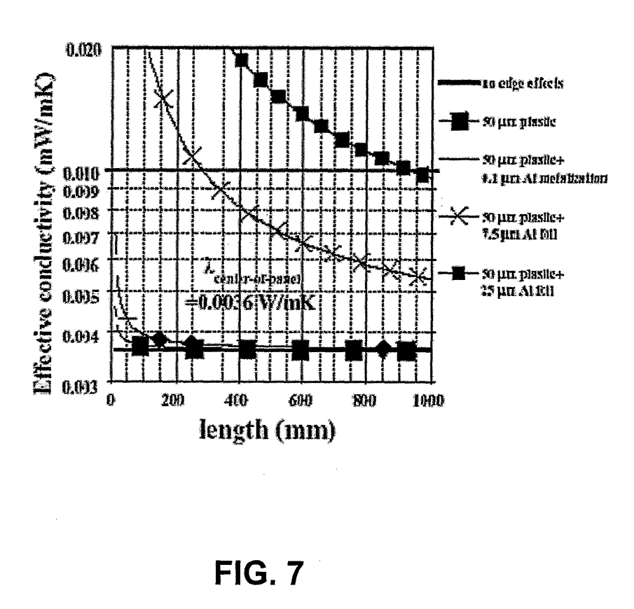

However, while films such as Aluminum films exhibit excellent impermeability and are not expensive to use, the high thermal conductivity of such films significantly increases the thermal loss rate of the insulated space. The high conductivity of the Aluminum film is clearly shown in FIG. 7. The figure reveals the effect of the film thickness and composition on the conductivity of different films. According to the graph, a thin Aluminum film (˜7.5 micrometer thick) with plastic lamination (50 micrometer thick) has a high conductivity at the edges that can clearly damage the insulation level of the panel (0.02 milliwatt per meter-Kelvin).

For example, as depicted in FIG. 7 600 mm of the core alone, or of a 600 mm film of plastic (˜50 micrometer thick) has conductivity of 0.002 milliwatt per meter-Kelvin. However, if the same 600 mm plastic film is coupled with a thin 600 mm Aluminum film (˜7.5 micrometer thick) the thermal conductivity of the film increases to 0.0066 milliwatt per meter-Kelvin. In should be noted that thermal conductivity of the same plastic film, increases only to 0.004 when coupled to a 600 mm film of stainless steel (˜5 micrometer thick).

FIG. 7 also reveals that using a plastic film or a film of plastic coated with very thin layer of aluminum (metallized film—typically with up to 300 angstrom of aluminum layer) are possible solutions to decrease conductivity of the panel edges. However, the aforementioned films have higher permeability to atmospheric gases and water vapors than Aluminum foils or other metal foils.

In order to reduce the thermal conductivity of the films without adversely affecting the maintenance of the predetermined pressure level and without hindering the ability to seal the panel, the lateral strip 3 is provided as a thermal barrier between the two panel walls 2. The lateral strip 3 is positioned to sealably enfold the films external edges 6, covering the lateral surface area of the panel.

Preferably, the panel walls are laminates which comprise an impermeable to gas layer and to water vapors layer other than aluminum film. An example for such a film is stainless steel film, multilayer metallized or coated films of PEN, PET, COC and other polymers, or a combination thereof.

Preferably, the lateral strip 3 and the panel walls 2 are made of the same material.

Preferably, the lateral strip 3 is a strip characterized by low thermal conductivity, having lower conductivity level than Aluminum when exposed to heat flow. The lateral strip 3 can be made from several layers of film, polymers, and metallized films of ceramic films or from a laminate containing thin metal strip. In order to reduce the insulation panel conductivity, the thickness of a metal foil barrier layer like stainless steel in the laminate of lateral strip 3 width is preferably ˜5-12 micron thick, and has a thermal conductivity level typically below 30 W·m⁻¹·K⁻¹ at 25° c. The few known materials that fit this description include Titanium alloy, Kovar® and Invar®, stainless steel, and many steel alloys.

It is noted that the materials listed are too expensive to use over the panel's entire surface. The materials are therefore not used over the whole surface but merely to provide a thermal barrier between the film layers. With such a thermal barrier the desired thermal conductivity level of the whole panel can be achieved more economically, without compromising on the impermeability properties of the envelope materials. The use of such a lateral strip 3 promises that the panel walls 2 do not touch each other at any point, and therefore, heat is transferred from one side to the other only via strip 3, which as it was said, has lower thermal conductivity.

In order to promise the solidity and the tightness of the panel and its relative impermeability to atmospheric gases and to water and water vapors, the lateral strip 3 is sealably joined to panel 6.

Preferably, a sealing strip 4 comprising an adhesive sealing material, or mixtures thereof, is laminated along the edges of the external side of the panel walls 6. The sealing strip 4 seals the gap between the edges of the external side of the panel walls 6 and the inner side of the lateral strip 3.

As with the panel's panel walls 2 and the lateral strip 3, the sealing strip 4 preferably functions as a sealing layer, substantially preventing the passage of atmospheric gases, water vapor and water from the external surrounding 7 into the panel's internal space 5.

Reference is now made to FIG. 1B, which depicts another exemplary, illustrative preferred embodiment of the present invention. The core 1, the panel walls 2 and the lateral strip 3 are as in FIG. 1A above however, in the present embodiment the sealing strip 4 was changed and an additional sealing strip was added.

In this preferred embodiment of the present invention, the sealing strip 4A is laminated all along the panel walls 2. In addition, an additional sealing strip 3A is laminated along the lateral stream 3. In this embodiment the laminated panel walls and the laminated lateral strip are, preferably, a laminate comprising several layers.

In one preferred embodiment the lateral strip 3 and the panel walls 2 can be made of multilayered laminate that comprises a thin metal layer. Such laminates are layered to provide a high barrier strip substantially impermeable to both atmospheric gases and to water vapor.

In one preferred embodiment of the present invention the aforementioned laminate comprises a combination of metallized Polyethylene teraphtalate (PET) or Polyethylene N-phthalate (PEN).

In another preferred embodiment, one of the aforementioned laminate layers is a metallized film being any of: Cyclic Olefin Copolymer (COC), Liquid Crystal Polymers (LCP) and Polyvinylidene Chloride (PVDC), and a barrier adhesive such as PVDC.

As the surface area of this lateral strip 3 is substantially smaller than the surface area of the panel walls 2 (around 3% to 8%, depending on panel wall length and the core 1 width) relatively expensive materials can be used to comprise the lateral strip laminate.

For example, in order to achieve good thermal insulation in high temperature surroundings (e.g. in refrigerated vehicles in which the walls are exposed to the sun where the cumulative temperature can reach 90°), a lateral strip 3 of laminate that comprises a thin layer of ˜5-˜12 microns of metal film with thermal conductivity lower than the thermal conductivity of aluminum film can be used.

Preferably, the lateral strip 3 comprises stainless steel or Kovar™, or Invar®. Alternatively titanium alloys can be used.

The integration of such a lateral strip 3 creates a metal cover that hermetically envelops the core. When a panel according to the present embodiment of the present invention is exposed to high temperatures, its impermeability level to atmospheric gases or water vapors remains very low.

However, when envelopes from other materials, such as laminates comprising layers of polymers or metallized polymers, are exposed to higher temperatures, their impermeability substantially decreases.

However, since a panel according to the present embodiment has a very good thermal barrier at room temperature, even materials with high thermal conductivity such as Aluminum can in fact be used for applications such as domestic freezers.

In one preferred embodiment of the present invention, the panel walls 2 and the lateral strip may further be laminated with a low conductivity coating layer. The low conductivity coating layer is adapted to sealably coat the external side of the panel walls and the lateral strip.

The coating layers may consist of any of the following: silicon oxide (SiOx), aluminum oxide Al₂O₃, and diamond like coatings. The coating is placed on a polymer such as PEN (polyethylene n-phthalate) PET (polyethylene tera-phthalate) PVOH (polyvinyl alcohol) COC (cyclic olefin copolymer) BOPA (bi-oriented polyamide) and BOPP (bi-oriented polypropylene).

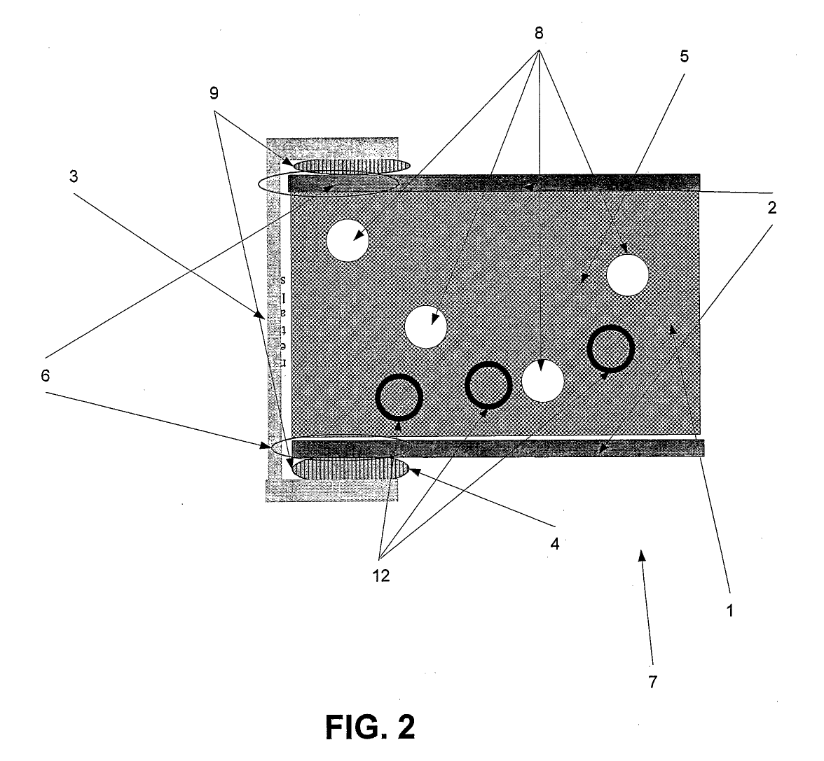

Reference is now made to FIG. 2, which depicts another exemplary, illustrative preferred embodiment of the present invention. The core 1, the panel walls 2 and the lateral strip 3 are as in FIG. 1A above however, in the present embodiment the sealing strip 4 is changed and a few more components are added.

In this preferred embodiment of the present invention the sealing strip 9 is made of rubber modified acrylonitrile.

The rubber modified acrylonitrile is much more flexible than regular acrylonitrile films. The rubber modification of the acrylonitrile creates a flexibility that can be used in the present application. Polymers of these types are offered commercially under the trade designation Barex® resins supplied by BP Chemicals International, part of INEOS Group. The Barex® sealing strip 9 forms a flexible sealing layer with low conductivity to heat.

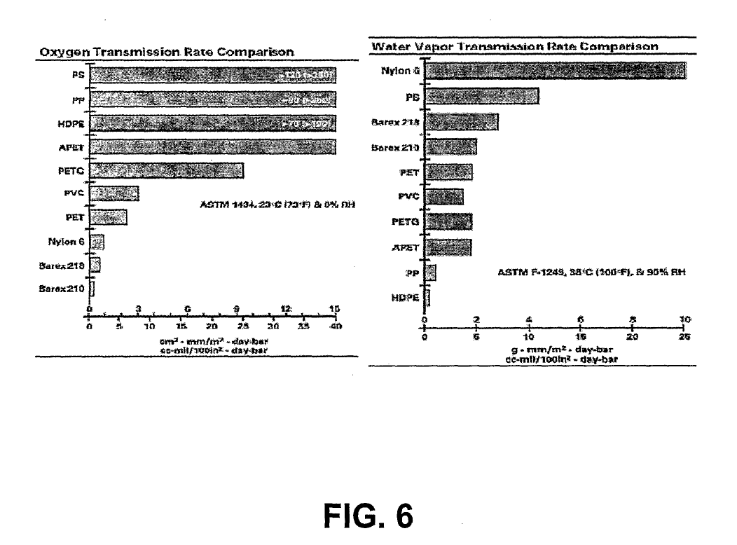

In addition, the Barex® sealing strip also constitutes a sealing layer for maintaining the vacuum with an oxygen transmission rate of less than 1 OTR (cc mm/m² day ATM) at 23° c., 0% rh. The superiority of Barex® as a sealing material with low oxygen transmission rate is clearly shown in FIG. 6 which reveals a comparative graph that depicts the transmission rate (cc mm/m2 day ATM) at 23° c., 0% rh of various sealing materials to both oxygen and water vapor. According to FIG. 6 Barex® has a much lower oxygen transmission rate than High-Density Polyethylene (HDPE) and Polypropylene (PP). However, the figure also demonstrates the Achilles heal of the Barex®—the high water vapor transmission rate relatively to HDPE.

In one preferred embodiment of the present invention, in order to prevent a decrease in the pressure level as a result of the accumulation of water vapor within the internal space of the panel, desiccating agents 8 are added to the internal space before the panel is sealed.

It should be mentioned that desiccants are less expensive than getters. Thus, the combination Barex® with desiccant agents is much more economical than the combination of getters with material which is substantially impermeable to water and water vapor, but relatively permeable to atmospheric gases, an example of such a moisture substantially impermeable material being high density polyethylene (HDPE).

Adding desiccating agents 8 to the sealed space allows long term absorption of water vapor molecules form the internal space of the panel. This is done by the ability of desiccating agents to absorb water and water vapor from the panel's internal space. Desiccating agents, which may be added to the panel, include CaO, molecular sieves, P₂O₅ and other known desiccants.

The combination of Barex® as a sealing material with the supplementation of desiccating agents to the panel's internal space provides a vacuum sealed panel with high impermeability to atmospheric gases and absorption abilities to prevent the accumulation of water vapors within the internal space of the panel. Thus, using the Barex®-desiccating agents' combination the panel's vacuum is kept for longer periods, sustaining the insulation level of the panel.

In one preferred embodiment of the present invention, getters 12 are added to the internal space before the panel is sealed. The getters, when active, absorb atmospheric gases from the internal space of the panel. Hence, the getters can substantially slow down the decrease of the pressure level due to accumulation of atmospheric gases within the internal space of the panel.

The getters 12 are inserted in order to prevent any remaining or penetrating gases from remaining in a free state in the evacuated sealed insulation panel.

Preferably, the getters 12 are small, circular troughs filled with rapidly oxidizing metals (e.g. Barium and) possible gas absorbing agent like molecular sieves can also be used.

In another preferred embodiment of the present invention the sealing strip 9 is made of polyvinylidene chloride or polyvinyl chloride or a blend thereof. The so formed sealing strip 9 likewise forms a highly effective sealing layer to atmospheric gases and water vapors.

In addition, such a sealing strip also constitutes a sealing layer for maintaining the vacuum with an oxygen transmission rate of less than 0.1 OTR (cc mm/m2 day ATM) at 23° c.

In another preferred embodiment of the present invention the sealing strip 9 is made of liquid crystal polymers.

The liquid crystal polymers are a family of polymers with very high barrier properties over a wide temperatures range. A sealing strip 9 of liquid crystal polymers forms a highly effective sealing layer.

Hence, such a sealing strip also constitutes a sealing layer for maintaining the vacuum, with an oxygen transmission rate of less than 0.1 OTR (cc mm/m² day ATM) at 23° c.

Other sealing materials that can be used are thermoplastic resin (PVC).

In one preferred embodiment of the present invention the sealing material is blended with nanocomposites of clay. Such a blend, for example using Montmorilonite, is done for raising the heat deflection temperature of the sealing material. Blending with nanocomposites of clays provides high levels of gas impermeability and thermoresistance.

The blending of nanocomposites of clay materials can increase the impermeability to gas 2-10 times. In addition, the mixture of sealing material and nanocomposites of clay materials has a higher heat resistance. Such a mixture creates a material with better fire resistance.

In addition, the blending usually enhances the heat deflection temperature of polymers, and thus allows a wider temperature window for welding the panel walls 2 with the lateral strip 3. Moreover, the blend usually improves barrier and mechanical properties.

In one preferred embodiment of the present invention the sealing material is blended with flame-retardants. This blending is done in order to reduce conflagration risk. Adding flame retardant reduces the polymer's tendency to burn. Types of flame-retardants that can be used include: Halogenated flame retardants (containing chlorine or bromine atoms), boron compounds and zinc borate.

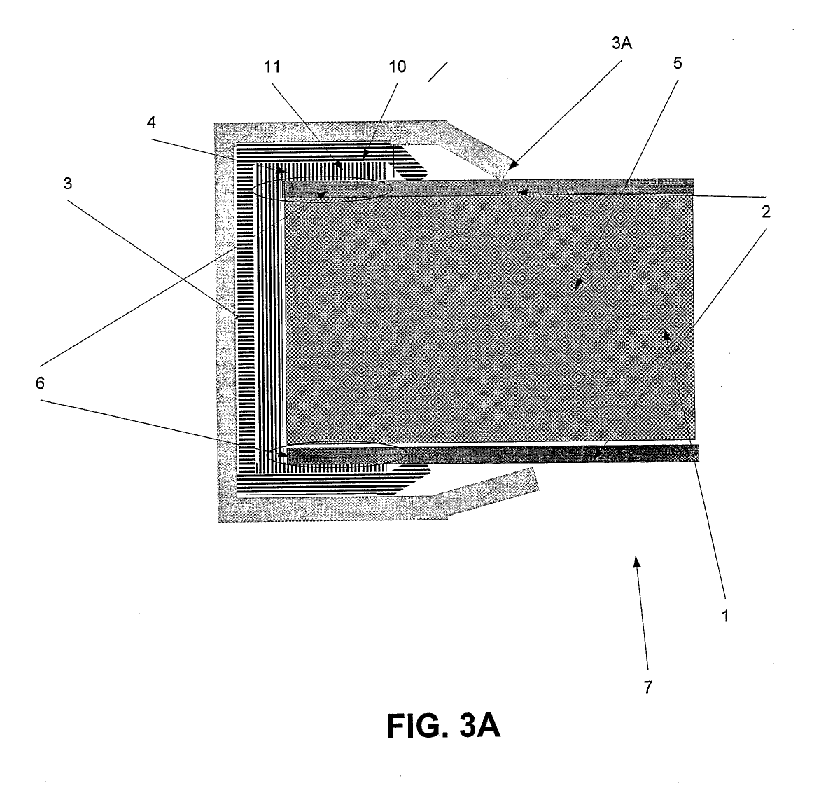

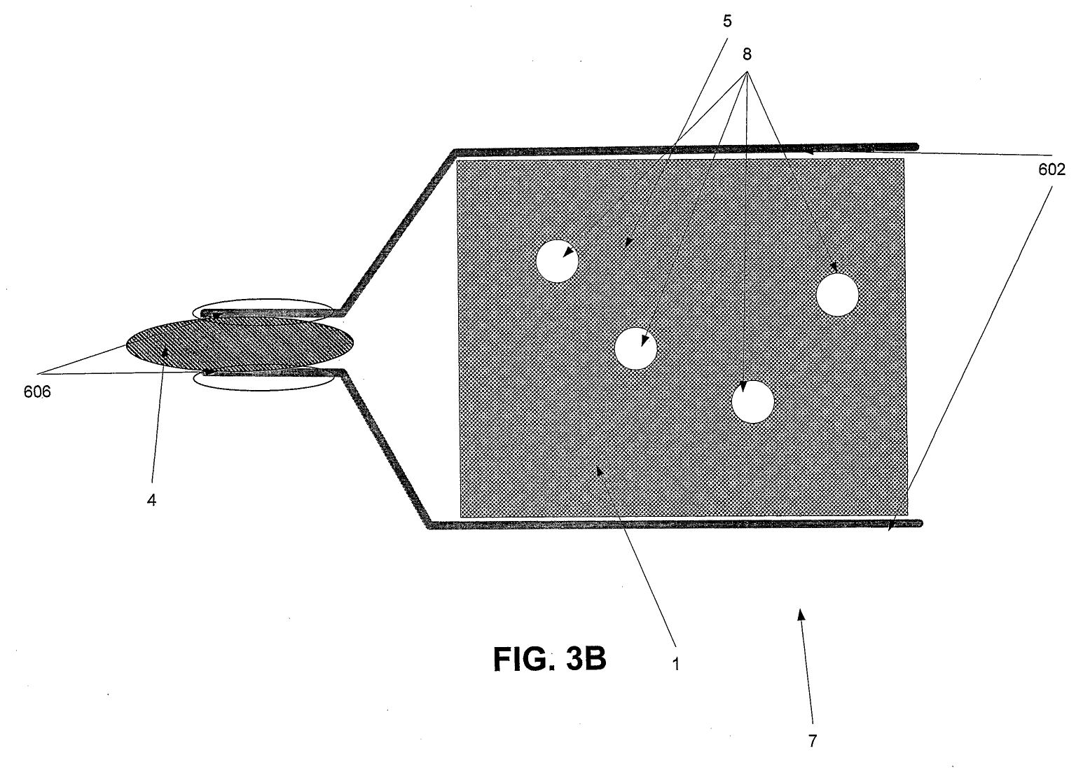

Reference is now made to FIG. 3A, which is another exemplary, embodiment of the present invention. The core of thermal insulation material 1 and the panel walls are as in FIG. 1A above, however, in the present embodiment the sealing strip and the lateral strip position and formation were changed.

In the present embodiment the sealing strip 4 is laminated along the lateral strip 3.

Preferably, the sealing strip 4 comprises two layers. The internal layer 11 is either a layer providing a low rate of atmospheric gases transmission or a layer providing a low rate of water and water vapor transmission. The external layer 10 is the complementary layer thereto, meaning it has the property not chosen for the inner layer. The external layer is laminated in such a manner that it completely and sealably covers the internal layer. The dual layer structure provides a high impermeability to both water and water vapors and to atmospheric gases. Since the external layer 10 completely covers the internal layer, there is no area along the dual layer which is permeable to either atmospheric gases or water and water vapors.

An example of such a dual layer strip is an external layer of Barex® 10, sealing the panel against oxygen & nitrogen, and an internal layer of polyethylene 11, sealing the panel against water and water vapor.

In this example, the external layer blocks the penetration of oxygen & nitrogen but does not efficiently block the passage of water and water vapors through the external layer. However, the internal layer blocks the water and water vapors which diffuses through the external layer. Since the external layer 10 completely covers the internal layer 11, oxygen & nitrogen cannot pass through.

Preferably, the external layer comprises HDPE.

In one preferred embodiment, the dual layer coats only the junction points 6 between the edges of the external side of the panel walls 2 and the inner side of the thermal barrier 3.

In this embodiment the layers are not positioned vertically one over the other but are laminated to overlap horizontally along the edges of the insulation panel.

Preferably, the lateral strip is slightly buckled 3A toward the external side of the panel walls 2 in order to sealably cover the welded area.

Reference is now made to FIG. 3B which depicts another exemplary, illustrative unique sealed panel for vacuum thermal insulation.

A sealing strip 4, according to this preferred embodiment, comprises a material which has two predetermined characteristics. The sealing strip 4 is designed to sealably join two panel walls 2 creating a sealed panel for thermal insulation.

In the state of the art, a commonly used material for sealing strips is high density polyethylene (HDPE). High density polyethylene is a thermoplastic made from oil with high resistance to many different solvents. HDPE is commonly used in the manufacturing process of envelopes for different containers (i.e. certain containers for milk, liquid laundry detergent, etc.).

HDPE has relatively high impermeability to water vapors and relatively low impermeability to atmospheric gases, as depicted in FIG. 6.

In this preferred embodiment the sealing strip is made from a material which was developed to substantially bar the passage of atmospheric gases from the external surrounding to the internal space of the sealed panel, and vise versa.

The first predetermined characteristic of the sealing material of the sealing strip is the level of impermeability to atmospheric gases. The second predetermined characteristic is the level of impermeability to water and water vapors. The sealing material impermeability to atmospheric gases is higher than the impermeability of High-Density Polyethylene to atmospheric gases. The sealing material the impermeability to water and water vapors is lower than the impermeability to water and water vapors of High-Density Polyethylene.

Hence, a sealing material with high level of impermeability to atmospheric gases was chosen, with compromising the sealing material's level of impermeability to water and water vapors.

Accordingly, the panel has high permeability to water and water vapors. In order to prevent a decrease in the pressure level as a result of the accumulation of moisture within the sealed panel as an outcome of the sealed panel's high permeability to water and water vapors, desiccating agents 8 are added to the internal space before the panel is sealed.

In one preferred embodiment of the present invention the sealed panel for vacuum thermal insulation comprises a core 1 made of thermal insulation material. The reverse and the obverse of the core 1 are covered with a film 602 of a material substantially impermeable to atmospheric gases and water vapor. Furthermore, desiccating agents 8 are positioned in the space between the films. A sealing strip 4 of a rubber-modified acrylonitrile copolymer (Barex®) sealably joining the edges 606 of the inner sides of the films.

In this embodiment the panel walls 2 and the Barex® 606 forms a sealed casing to the core of insulation material 1. The casing can be evacuated of atmospheric gases and moisture in order to increase the panel's insulation level.

In addition, the positioning of the Barex® 606 as a thermal barrier between the two films prevents heat transfer from one film to the other.

However, in order to efficiently retain the low thermal conductivity of the core of insulation panel, a strip of low conductivity material should separate between the two panel walls 2.

Hence, a panel according to the present embodiments has low heat conductivity and can insulate cooling rooms efficiently.

It should be mentioned that the addition of desiccating agents 8 to such a panel is important. The Barex® 606, as described above, has relatively high permeability to moisture. In order to prevent a decrease in the pressure level as a result of the accumulation of moisture within the internal space of the panel, desiccating agents 8 are added to the internal space before the panel is sealed, as described above.

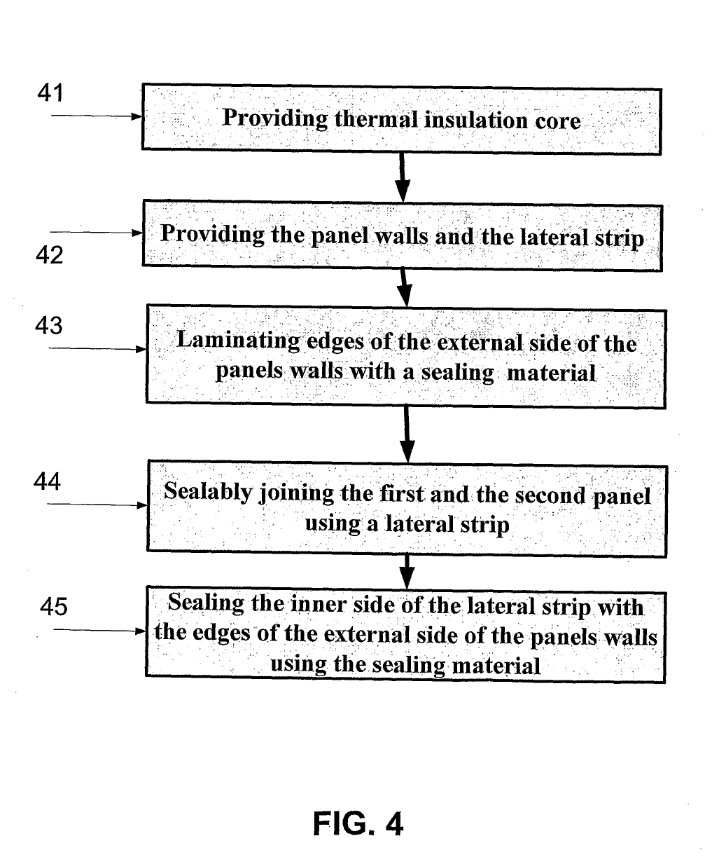

Reference is now made to FIG. 4, which is a simplified flowchart of an exemplary method according to a preferred embodiment of the present invention. The method depicted in FIG. 4 follows the manufacturing steps of a sealed vacuum thermal insulation panel.

Generally, in the production of the evacuated insulation panel, the aim is to manufacture a panel evacuated from atmospheric gases and moisture, having walls of material substantially impermeable to atmospheric gases and water vapor to maintain the predetermined pressure level.

Accordingly, the first step 41 be to provide a thermal insulation core. The second step 42 is to provide two panel walls of panel walls 2 of material substantially impermeable to atmospheric gases and to water vapor and a lateral strip of the same or another material substantially impermeable to atmospheric gases. The panel walls are positioned to cover the reverse and obverse sides of the core of thermal insulation material, the thermal insulation core thermal insulation core lateral surface area is still uncovered.

Preferably, the internal side of the panel walls is laminated with an adhesive layer. In use, the adhesive layer firmly attaches the panel walls to the reverse and obverse sides of the core of thermal insulation material.

In the next step 43, the external side of the panel walls and the internal side of the lateral strip are laminated with a sealing material coating layer.

In one preferred embodiment of the present invention, the external sides of the panel walls and the lateral strip are laminated with an additional layer. One of the layers is material substantially impermeable to atmospheric gas and the other is material substantially impermeable to water and water vapor. By doing so, the panel impermeability to molecules from the outer surrounding increases, and accordingly the ability to maintain higher level of pressure for longer periods.

During the subsequent step 44, the lateral strip is positioned to sealably join the two panel walls, covering the lateral area of the panel. The lateral strip is shaped to cover the sealing material layer, enfolding the insulation panel walls. Accordingly, the lateral strip and the panel walls form a casing which is impermeable to gases and moisture to enclose the thermal insulation core.

It should be noted that one important advantage of this invention is the accessibility to the sealing material coating layer.

The sealing material coating layer of the lateral strip and the panel walls may have small cracks that can open a passage for atmospheric gases and water vapors to penetrate the internal space of the panel, causing a decrease in the predetermined pressure. Hence, it is important that the sealing material coating layer is easily accessed and thereby easily resealed.

Subsequently, during the next step 45 the sealing process is initiated and the inner side of the lateral strip is welded with the edges of the external side of the panel walls.

Preferably, the sealing material coating layers are used to create a continuous metallic bond between the lateral strip and the edges of the external side of the panel walls.

Preferably, the sealing material coating layers comprise more than one metal type. The metal types have different thermal conductivity.

Preferably, during the welding process a small cavity on the junction between the lateral strip and the edges of the external side of the panel walls remain unsealed. The resulting cavity facilitates the evacuation of air as described below.

In another preferred embodiment of the present invention, the cavity is integrated in one of the panels.

In this preferred embodiment of the present invention, the sealing is done on the external side of the panel walls. Hence, in case of a puncture, a patch of a laminate of the same sealing material coating layers can be used to seal the punctuated area.

The sealing material coating layers can be easily accessed, facilitating the repair of the cracked area.

Preferably, the patch is made of a laminate that comprises a barrier layer, and a sealing layer. In use, the patch is positioned to overlie the puncture and the sealing layer is heated. The heating sealably unifies the sealing and the panel thereby seals the puncture.

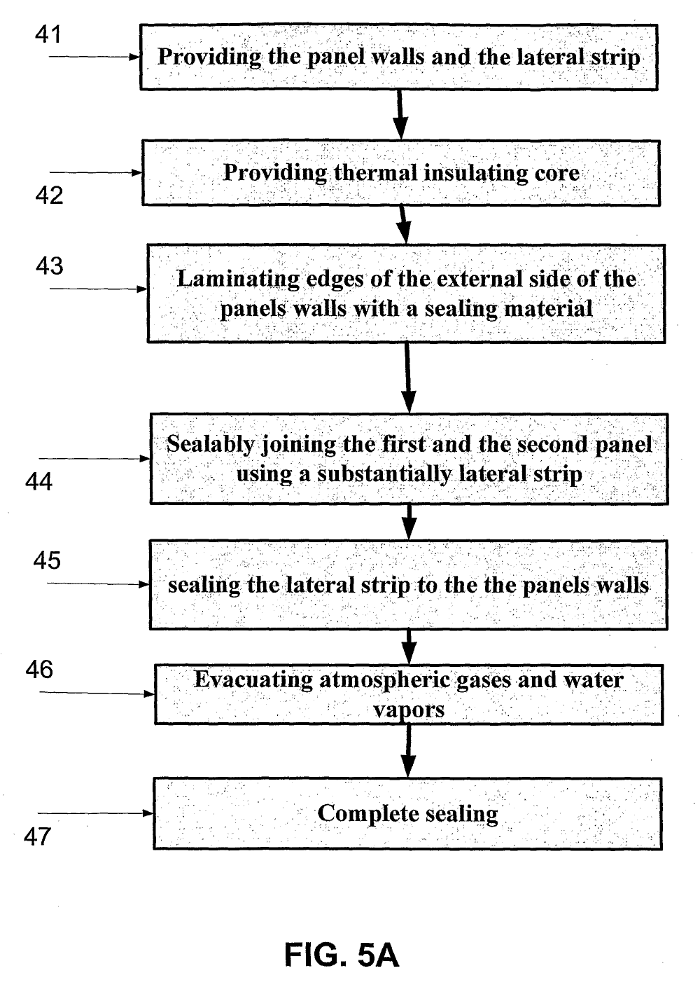

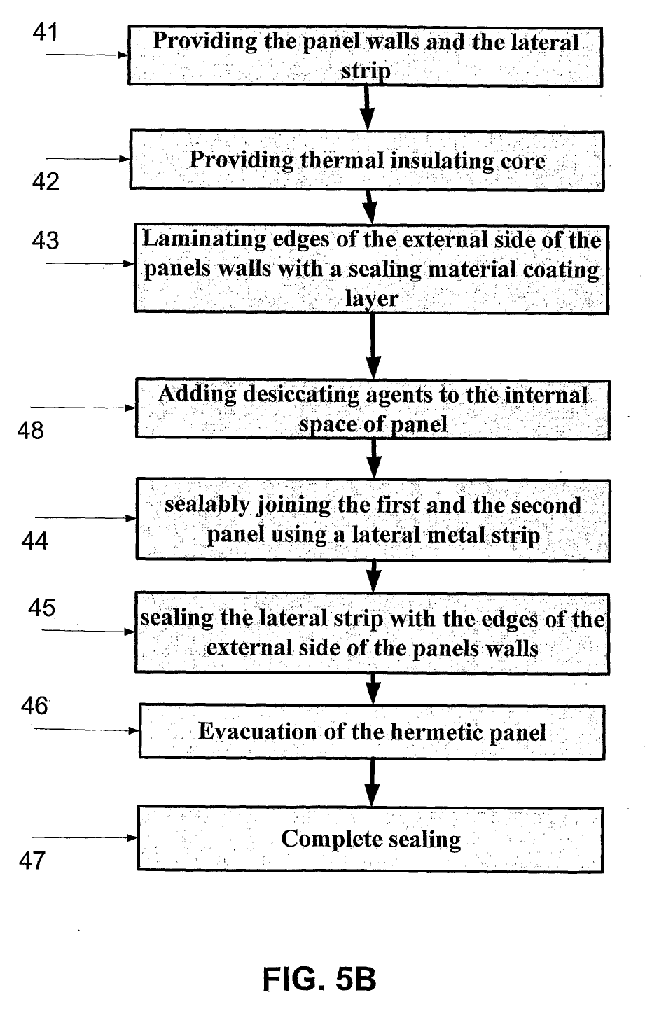

Reference is now made to FIG. 5A, which is another flowchart of an exemplary method according to another preferred embodiment of the present invention. Steps 41-45 are as in FIG. 4 above however, step 46 and 47 were added.

In FIG. 5A, the sealing step 45 is followed by two additional steps. During the first additional step 46 all of the atmospheric gases and moisture are evacuated from the internal space which is formed between the panel walls and the lateral strip. Preferably, in order to evacuate the internal space of the panel, an evacuation tube and a vacuum pump are used. The evacuation tube comprises two end connections, one end connection is connected to a vacuum pump and the other end connection is designated to fit an unsealed cavity on the panel sealing.

At the outset of the evacuation, the tube is inserted into the unsealed cavity. Subsequently, the activation of the vacuum pump initiates the evacuation process.

Preferably, the evacuation pump is operated until the pressure level within the internal space of the panel reaches the predetermined pressure level, typically between 0.1 millibars and 200 millibars.

During the following step 47, the unsealed cavity is patched. The patching of the cavity finalizes the process of creating a sealed panel evacuated from atmospheric gases and water vapor.

Usually the sealing of evacuated panels is done by applying pressure on the panel and heating the panel walls thereby melting or welding the sealing material coating layer on the external side of panel walls and on the internal side of the lateral strip thereby sealably joining the panel walls.

In one preferred embodiment of the present invention, the sealing of the panel is done using a roller, also referred to as thermal lamination, or encapsulation. The roller is used to apply pressure on the area the lateral strip tangent the edges of the external sides of the panel walls. The applied pressure seals the sealing material, thereby closing the seam between the lateral strip and the edges of the external side of the panel.

In one preferred embodiment of the present invention, the sealing uses Radio Frequency radiation. The Radio Frequency (RF) sealing, sometimes known as Dielectric sealing or High Frequency (HF) sealing, is used to fuse the sealing materials together with the lateral strip and the panel walls by applying radio frequency energy on the sealing material strip. The RF welding relies on certain properties of the sealing material to cause the generation of heat in a rapidly alternating electric field.

Hence, the used sealing material must be adjusted to be activated using RF radiation. A small number of known materials that fit this description include Barex®, PVC and PVDC.

In a preferred embodiment of the present invention, the lateral strip is fully or partly transparent to RF radiation. In order to facilitate this feature the lateral strip cannot comprise Aluminum, metal foils and other metallized foils per se.

Preferably, the lateral strip is coated with a barrier coating layer of, for example, Silicon Oxide or Aluminum Oxide.

Such a lateral strip facilitates the welding of the sealing strip using RF transmitter since the lateral strip does not block the radiation facilitating its arrival to the sealing strip which is laminated in-between the lateral strip and the panel walls. The RF waves cause the welding of the sealing strip to the panel walls and to the lateral strip. The process revolves around subjecting the sealing strip to a high frequency (13-100 MHz) electromagnetic field to heat it and thereby bring about the seal.

In the present embodiment, the sealing strip material is affected by the radiation. Hence, only certain sealing materials can be used.

Preferably, the sealing material is rubber-modified acrylonitrile copolymer (Barex®), Polyvinylchloride (PVC).

Preferably, the welding is done by both Radio Frequency radiation as described above and by applying pressure using a roller.

In another preferred embodiment of the present invention, the sealed panel is further coated with a ceramic material layer on a polymer substrate. The advantage of such a layer is that it is transparent to RF transmission and has high barrier to atmospheric gases and water vapors.

Reference is now made to FIG. 5B, which is a simplified flowchart of a method according to another preferred embodiment of the present invention. The steps of providing thermal insulation material, panel walls and the lateral strip, the laminating step, welding step and evacuating step are as in FIG. 5A above however, the present embodiment further comprises a step of providing desiccating agents. The preferred embodiment deals with the issue of and water vapors accumulation when using sealing material with a higher rate of water and water vapor transmission (e.g. Barex®) than HDPE.

In order to avoid the accumulation of moisture within the boundaries of the sealed panel, desiccating agents are added to the internal space of panel 48. The desiccating agents are added before the lateral strip is positioned to enfold the edges of the panel 44.

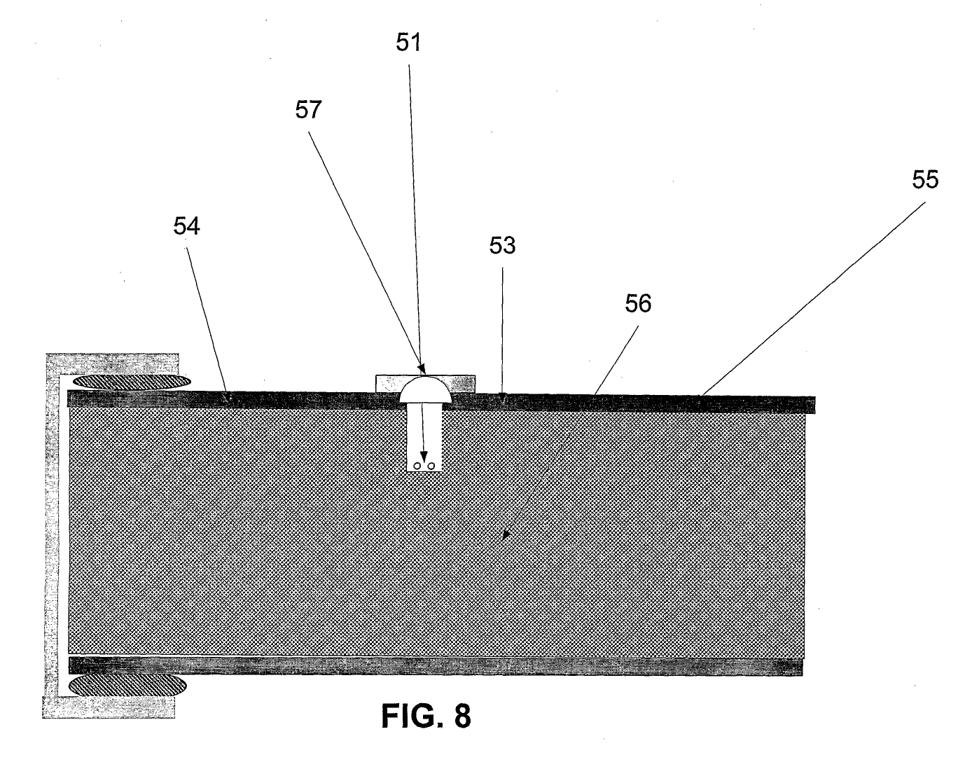

Reference is now made to FIG. 8 which depicts an exemplary, sealed panel for vacuum thermal insulation which has a fixed vacuum valve 51 for allowing the initial evacuation of the insulation panel and for periodic maintenance of the pressure level range within the panel's internal space.

Preferably, the vacuum valve 51 is sealably positioned within an aperture 53 formed in the panel sealing 54 of an evacuated thermal insulation panel 55.

As mentioned before, vacuum thermal insulation panels are used to insulate insulation units and rooms for long periods, such as ten to sixty years or even more. During such a lengthy period even a well-sealed container is likely to lose vacuum. The loss of pressure or the rise on internal pressure leads to a decrease in the insulation provided by the panels or an increase of the thermal conductivity of the panel.

Hence, in order to maintain the insulation level of the panel, a tool for restoring and maintaining the vacuum is needed.

The present embodiment comprises a vacuum thermal insulation panel that includes a permanent vacuum valve 51. The permanent vacuum valve 51 is adapted to sealably overlie an aperture 53 in the panel sealing 54, preventing the passage of atmospheric gases or water vapors to or from the inner space of the panel 56. The permanent vacuum valve 51 is generally closed, not impairing the predetermined pressure level within the panel's internal space. The body of the valve is located mostly within the panel's internal space 56, having only the suction interface 57 on the outer surface of the panel. Therefore, the valve does not interfere with the outer geometry of the panels, and allows smooth positioning of the panel along the walls of the insulation unit or the cooling room, in proximity to other panels.

The vacuum valve comprises a suction interface 57 having one end for connection to the vacuum valve 51 and another end for connection to a source of vacuum suction, such as a vacuum pump.

In use, the vacuum valve is connected to a suction source or to an adaptor via the suction interface 57.

Preferably, a spout 52 which is adapted to encircle the vacuum valve 51 sealably overlies the aperture 53 of the sealing layer 54. In this embodiment the vacuum valve 51 is not firmly fixed to the thermal insulation panel 55, but positioned within a spout 51.

Preferably, the spout is made of an injected molded polymer using Barex® and has a relatively wide flat flange that creates a thermal sealing surface which covers the aperture within the panel sealing 54.

In addition, since the spout is directly coupled to the panel sealing it is important that it remains substantially impermeable to atmospheric gases. Using permeable material for the spout can clearly reduce the pressure level within the insulation panel. Hence, Barex®, which is substantially impermeable to atmospheric gases, is a good raw material for the spout.

Insulation panel walls are frequently made from a thin film of Aluminum or other substantially impermeable to gases and water vapors films. Such films can easily be damaged, cracked or punched. Any crack or puncture in the film can lead to a substantial increase in the pressure level. In order to repair such damaged films, the cracks and the punctures may be patched and the moisture and atmospheric gases may then be evacuated, to restore the predetermined pressure level within the panel. Such evacuation is easily achieved using the valve.

However, not all insulation panels comprise a vacuum valve that facilitates the evacuation. A spout comprising a vacuum valve can be helpful if integrated into the panel. After the crack or puncture is sealed, vacuum valve can be used to evacuate the internal space of the insulation panel.

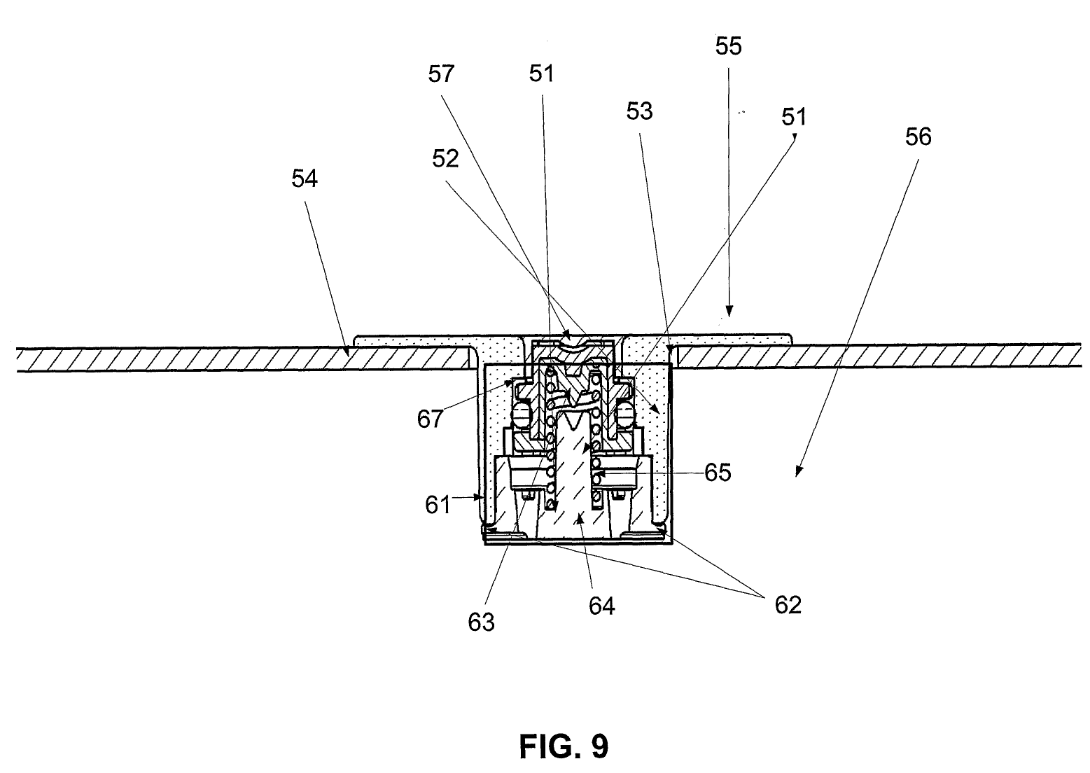

Reference is now made to FIG. 9 which depicts an exemplary, permanent valve for maintaining the predetermined pressure level range within vacuum sealed thermal insulation panels. The vacuum sealed panel and the aperture are as in FIG. 8 above, however, FIG. 9 depicts more thoroughly the components of a preferred vacuum valve according to one embodiment of the present invention.

FIG. 9 depicts, according to a preferred embodiment of the present invention, a vacuum valve 51 positioned within a spout 52 that comprises a chamber 61 having evacuation apertures 62 turned toward the internal space of the panel 56 and a valve stopper 63.

The vacuum valve 51 further comprises a spring recess 64 coupled to the chamber's bottom side. A spring 65 is threaded on the recess 66, pressing the valve stopper 63 toward a niche 67 in the spout 52.

Preferably, a flexible polymer ring as an O-ring is placed is the aforementioned niche. The pressure on the o-ring seals the vacuum valve.

The valve stopper 63 is blocked by the spout 52, covering the spout evacuation orifice. Hence, when the spring 65 is released, the valve stopper keeps the valve 51 closed, preventing the passage of gases and water vapors.

When the valve stopper 63 is pressed the vacuum valve is opened. When opened, the evacuation apertures 62 facilitate the passage of gases and water vapor from the internal space of the panel 56 toward the suction source.

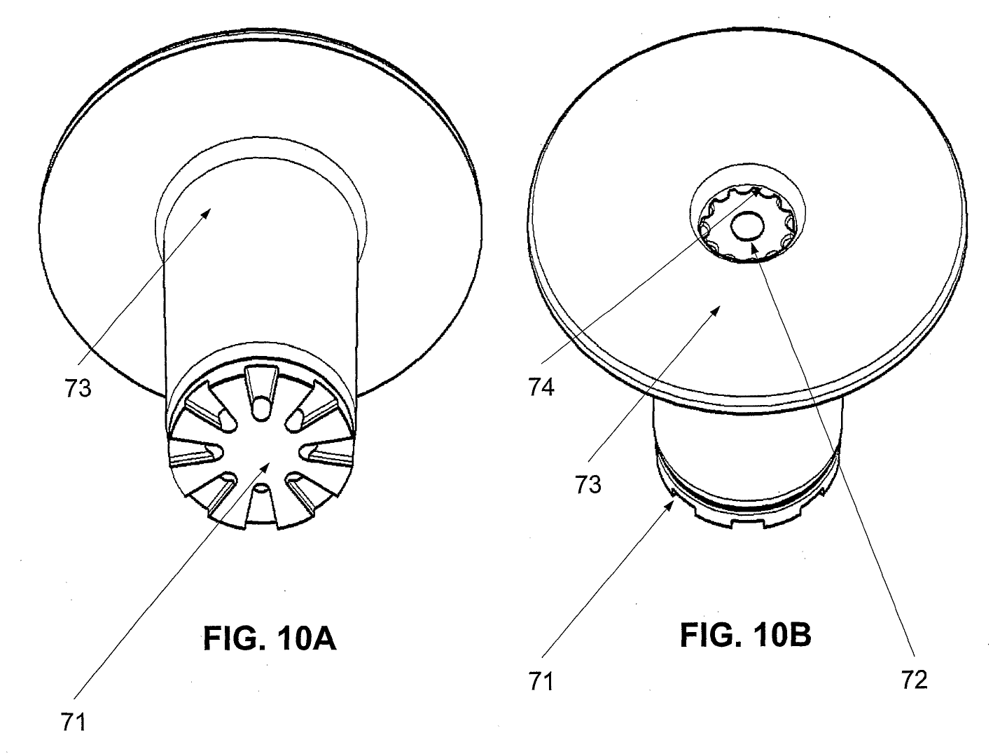

FIG. 10A is an external perspective view of a spout enveloping a vacuum valve showing the bottom surface thereof.

FIG. 10B is an external perspective view of the spout enveloping the vacuum valve showing the top surface thereof.

The floor passages 71 on the bottom facilitate the passage of atmospheric gases and water vapor. The structure of the floor passages 71 can function as a filter preventing particles of the thermal insulation materials which is located in the internal part of the panel from blocking the valve evacuation apertures.

The valve stopper 72 on the top of the valve, when pressed to be opened, facilitates the passage of atmospheric gases and water vapor via the upper evacuation apertures 74. As clearly shown in FIG. 10B the valve stopper 72 is wrapped up within the spout 73. The spout 73, according to the preferred embodiment of the present invention, reduces the chances that the stopper valve 72 is erroneously pressed. Moreover, as elaborated above, the architecture of the spout 73 ensures that neither the spout 73 nor the vacuum valve interrupt the positioning of the panel within an insulation unit.

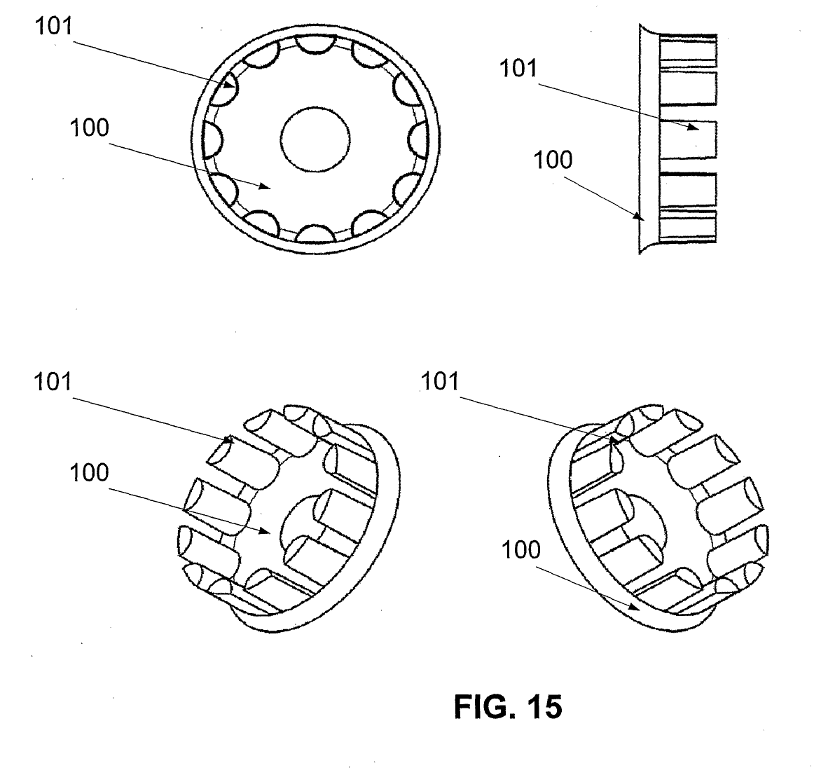

Reference is now made to FIG. 15 which depicts an exemplary, valve plug from four different points of view. The valve plug is adapted to be connected to the vacuum valve via upper evacuation apertures. The valve plug fills the upper evacuation apertures of the vacuum valve, preventing accumulation of air within the evacuation apertures. The figure depicts a preferred embodiment of a removable plug 100 having protrusions 101 to fit the evacuation apertures within the vacuum valve. Since the aim of the vacuum valve is to maintain the predetermined range of pressure level within the vacuum thermal insulation panels, atmospheric gases and moisture preferably do not pass through the vacuum valve when the vacuum valve is closed. In one preferred embodiment of the present invention, the evacuation apertures of the vacuum valve are opened when the vacuum valve stopper is pressed.

However, since there is a chance that the atmospheric gases will pass through the evacuation apertures in the proximity of the vacuum stopper, another sealing apparatus is needed.

Preferably, a patch can also be used as an additional sealing layer on top of the valve stopper. Such a patch can be used to sealably cover the vacuum valve, preventing any passage of air through the top evacuation holes of the vacuum valve. Yet, atmospheric gases and water vapors can still be trapped in-between the patch and the vacuum valve, or may penetrate the gap between the patch and the panel sealing.

Hence, the removable plug 100, according to one preferred embodiment of the present invention, constantly seals the aforementioned evacuation apertures of the vacuum valve using protrusions 101 adjusted to sealably plug the evacuation apertures.

The removable plug 100 is plugged to the vacuum valve and removed only for enabling the evacuation procedure. In addition, when the removable plug 100 is plugged, the protrusions 101 are superimposed within the evacuation apertures of the stopper, fixing the stopper in place, preventing any undesirable movements of the stopper that could lead to undesirable opening of the stopper. Preferably, the removable plug is made of rubber or flexible polymers.

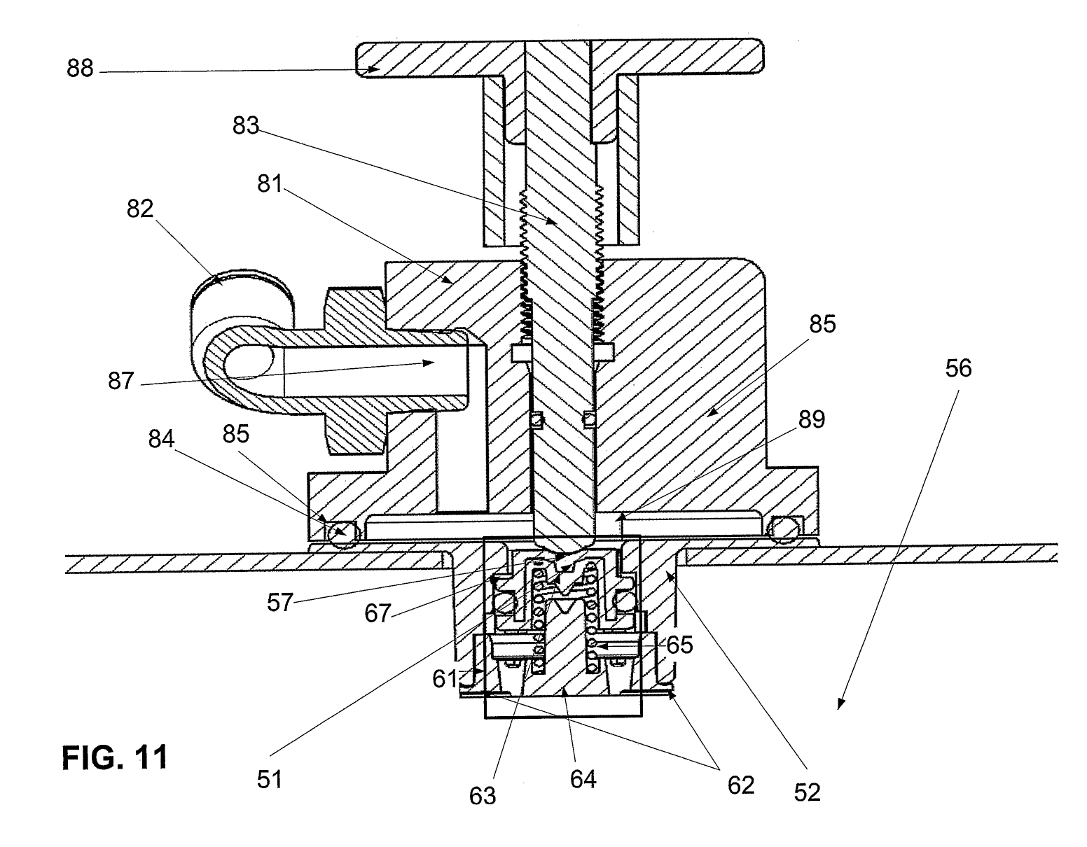

Reference is now made to FIG. 11 which depicts an exemplary permanent vacuum valve connected to a vacuum valve pump adaptor. The vacuum valve and all associated elements are as in FIG. 9 above, however FIG. 11 further depicts a vacuum pump adaptor.

The vacuum pump adaptor 81 comprises a readily removable pedestal 85 having a bottom duct 89 for sealably connecting a permanent vacuum valve 51 and a top outlet 82 for sealably connecting a suction apparatus. In addition, a pivot 83 is screwed through the readily removable pedestal 85. The pedestal has a rotating handle 88 for facilitating the screwing or the unscrewing of the pivot 83. The pivot 83 retains the vacuum valve 51 open during the suction transfer.

More practically, according to one preferred embodiment of the present invention, as described above, the opening of the vacuum valve 51 is done by pressing the valve stopper 63, thereby applying pressure on the spring 65.

Preferably, the valve stopper 63 is placed within a cavity in the spout 57. The present embodiment facilitates the use of a complementary shape as an interface to apply pressure on the valve stopper 63. Not all vacuum pumps or suction tools are adjusted with such a complementary shape to interface with such a valve. Hence, in the present embodiment a vacuum pump adaptor 81 is provided to interface, between the vacuum valve 51 and different vacuum pumps.

In one preferred embodiment, the adaptor 81 is coupled to the spout 52 using a loop of elastomer 84 with a round cross-section (O-ring). The O-ring is situated in a groove 85 within the adaptor pedestal 85 and compressed during assembly between the adaptor 81 and the spout 52, creating a seal at the interface. The hermetic coupling is achieved by the force created by the suction transfer in the internal space of the adaptor 89. The vacuum pressure pushes the adaptor removable pedestal 85 towards the spout 52 and hermetically couples the removable pedestal 85 to the panel.

Preferably, the adaptor 81 further comprises a connection to a suction source 82.

Preferably, the connection is rotatable around the horizontal axis, facilitating the interface with vacuum pumps from different angles.

The coupling of the adapter 81 to the spout 52, as described above, creates a gas and moisture passage 87 between the suction interface 57 and the suction source which may be connected to the suction source 82, such as a vacuum pump. When the valve stopper 63 is pressed to be opened, the passage 87 facilitates the evacuation of atmospheric gases and moisture from the internal space of the panel 56. The aforementioned evacuation maintains the predetermined pressure level within the panel.

Another key component of the adaptor 81 is the pivot 83. As depicted in FIG. 11, the pivot is screwed through the pedestal 85 in a manner such that the screwing applies pressure on the valve stopper 63, causing the opening of the vacuum valve 51 to air and water vapors. By doing so, the pivot 83 opens the last barrier in the passage 87, facilitating the evacuation of the internal space of the panel 56 using a suction source which is not adapted to the vacuum valve 51.

Preferably, an o-ring is positioned to seal the gap between the pivot and the pedestal.

Preferably, a rotating handle 88 is coupled to the pivot 83, facilitating the screwing or the unscrewing of the pivot 83.

In use, the adaptor creates a unique pressure environment around the valve, prior to the valve opening. The pressure level within the adaptor is either the same or even lower than the pressure level within the internal space of the panel. Preferably, the pressure level within the adaptor is decreased to a pressure level which is equivalent or lower to the desirable predetermined pressure level within the insulation panel (e.g. 0.01 millibar).

Subsequently, the pivot is used to open the valve, as described above, facilitating the suction of atmospheric gases and water vapors from the internal space of the panel. In this manner, the pressure inside the panel does not rise during the opening of the valve.

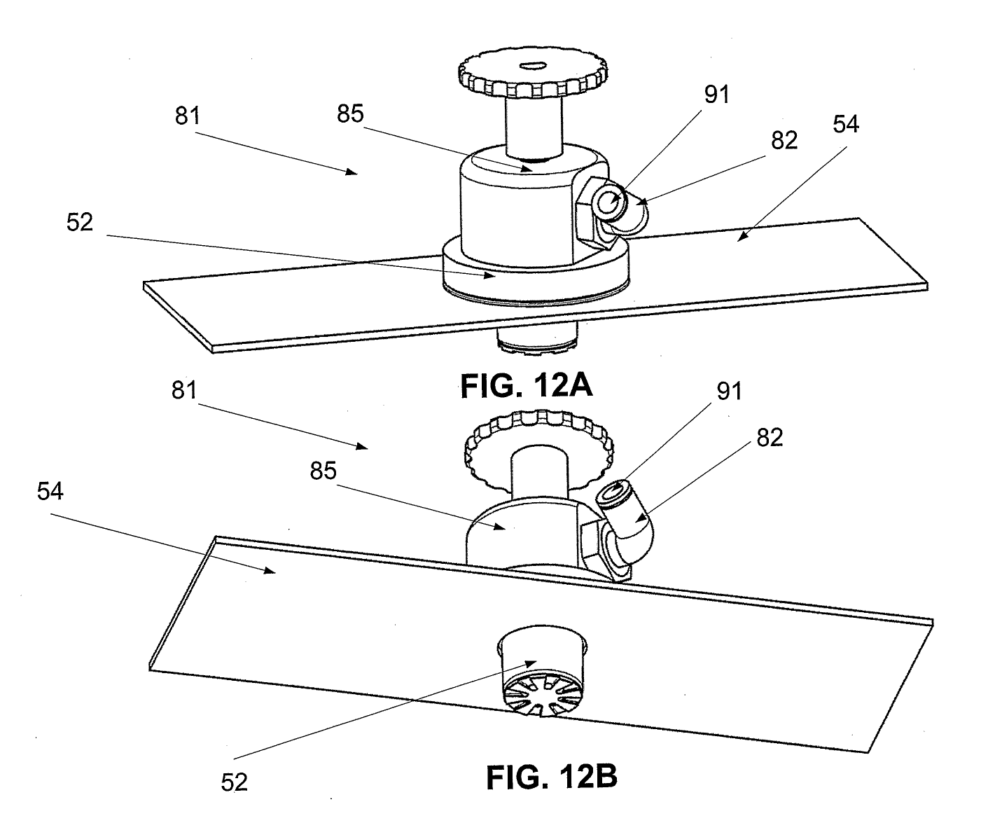

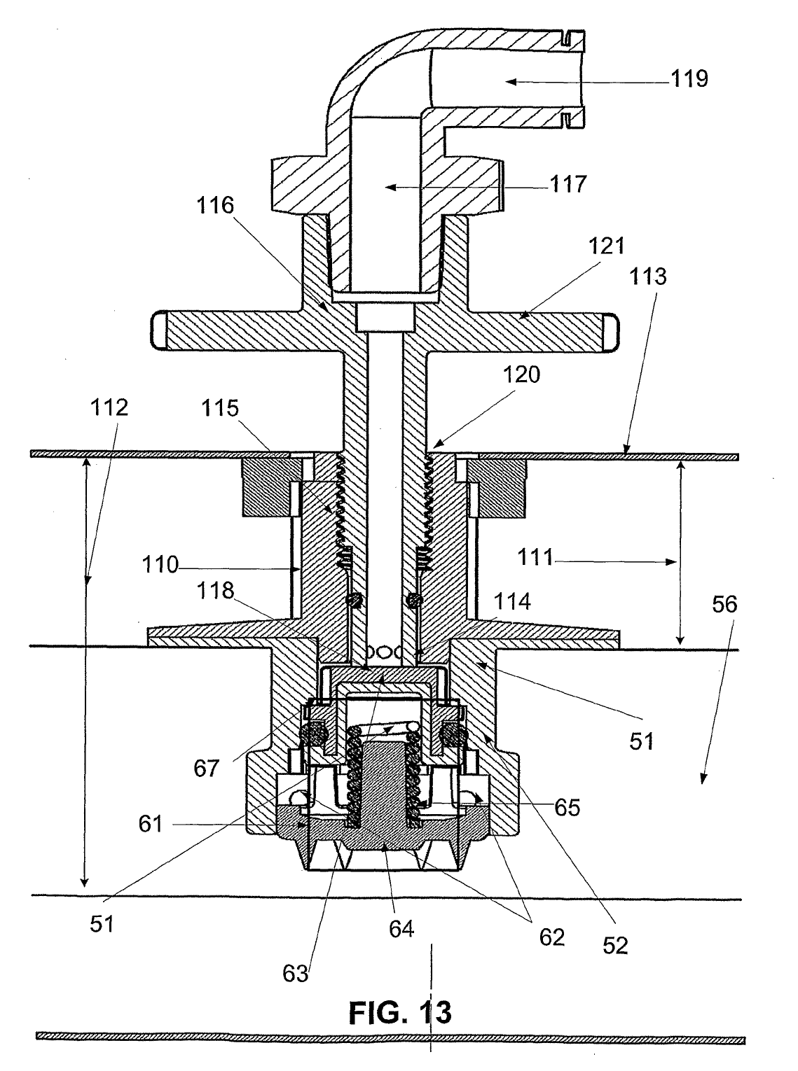

FIG. 12A is an external perspective view of the adaptor 81 connected to the spout 52 positioned in a panel wall 54 showing the top surface thereof.

FIG. 12B is an external perspective view of the adaptor 81 connected to the spout 52 positioned in a panel wall 54 showing the top surface thereof.

Preferably, thermal insulation panels are positioned at different angles along the inner side of an insulation unit, and the angular positioning of different vacuum valves can be different, making access awkward and making it difficult to connect a suction source to the adaptor. Hence, in order to facilitate easy access to the vacuum valve, a universal adaptor that facilitates the adjustment of the suction source end connection to cater for different angles would be highly advantageous to have.

FIGS. 12A and 12B demonstrate one preferred embodiment of the adaptor according to the present invention. In this preferred embodiment, the suction source end connection 82 is a nozzle with a right-angle bend, which is sealably coupled to the adaptor pedestal 85. The nozzle being so shaped facilitates angular adjustment of the suction source end connection 91.

The adapter 81 is applicable to all panels that comprise such a vacuum valve 51. Hence, only one adaptor 81 is needed to maintain the evacuated thermal insulation panel which where adjusted to fit the adaptor 81 according to this preferred embodiment of the present invention.

Preferably, the adaptor and the vacuum pump are part of a designated technician kit. Since the maintenance is not done on a day to day basis, such a kit need only be supplied to technicians.

Reference is now made to FIG. 13 which depicts an exemplary, illustrative unique permanent vacuum valve connected to a permanent adaptor pedestal. The vacuum valve and the evacuated thermal insulation panel are as in FIG. 9 above however FIG. 13 further depicts a linking fitting and an applicable adaptor. The linking fitting 110 is positioned in-between a thermal insulation panel 56 and an aperture 120 in the partition wall. The linking fitting 110 comprises a tube 115 having one end to connect the vacuum valve 51 through a designated duct 114 and another end to connect a designated screw-like pivot 116, through a designated aperture 120. The screw-like pivot 116 is screwed through the linking fitting 110, which is designed to connect between the linking fitting 110 and a suction source.

Evacuated thermal insulation panels are generally used in cooling rooms and insulation units, as explained. In some cooling rooms and insulation units the panels are positioned behind a partition wall or film. In order to facilitate simple maintenance of the evacuated thermal insulation panels an instrument that facilitates access to the panel's vacuum valve through the partition wall is preferably provided.

In one preferred embodiment of the present invention, a linking fitting 110 is placed between the vacuum valve 51 and the partition wall 113. The linking fitting 110 resembles the pedestal outlined in FIG. 11 and FIG. 12 (FIG. 11, numeral 81). However, in the present embodiment the linking fitting 110 is not coupled to a pivot or to an end connection adapted to a vacuum pump (FIG. 11, numeral 81, 82). The linking fitting is rather connected from one end to the vacuum valve 51, through a designated duct 114 and from another end is connected to an aperture in the partition wall 120.

Preferably, the linking fitting is made from Barex®.

Additionally, the linking fitting 110 further comprises an internal tube forming an internal screw thread 115 to be fitted onto a screw-like pivot 116.

The screw-like pivot 116 comprises an internal tube 117 having one end for connection to the vacuum valve 118 and another end for connection to the source of vacuum suction 119.

As depicted in FIG. 13, the screw-like pivot 116 is screwed through the linking fitting 110 in a manner that screwing the screw-like pivot 116 applies pressure on the valve stopper 63, causing to the opening of the vacuum valve 51. By doing so, the screw-like pivot 116 opens the last barrier in the passage 87, and thus facilitates the evacuation of the internal space of the panel 56. A rotating handle 121 is coupled to the screw-like pivot 116, facilitating the screwing or the unscrewing of the screw-like pivot 116. The screw-like pivot 116 is detachable and therefore can be use to maintain more then one panel. Moreover, since the screw-like pivot 116 is detachable the insulation panels take less room.

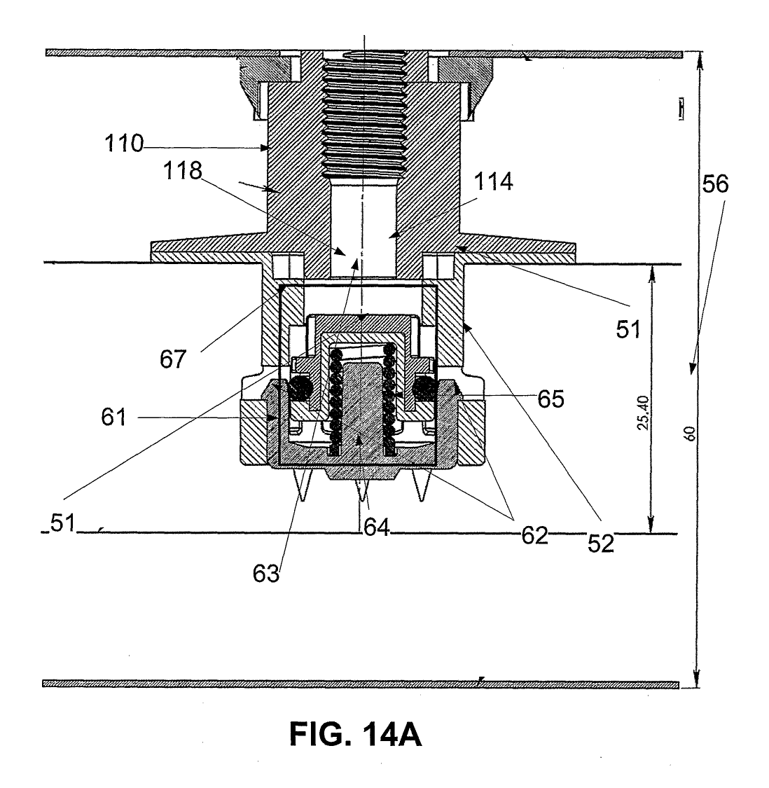

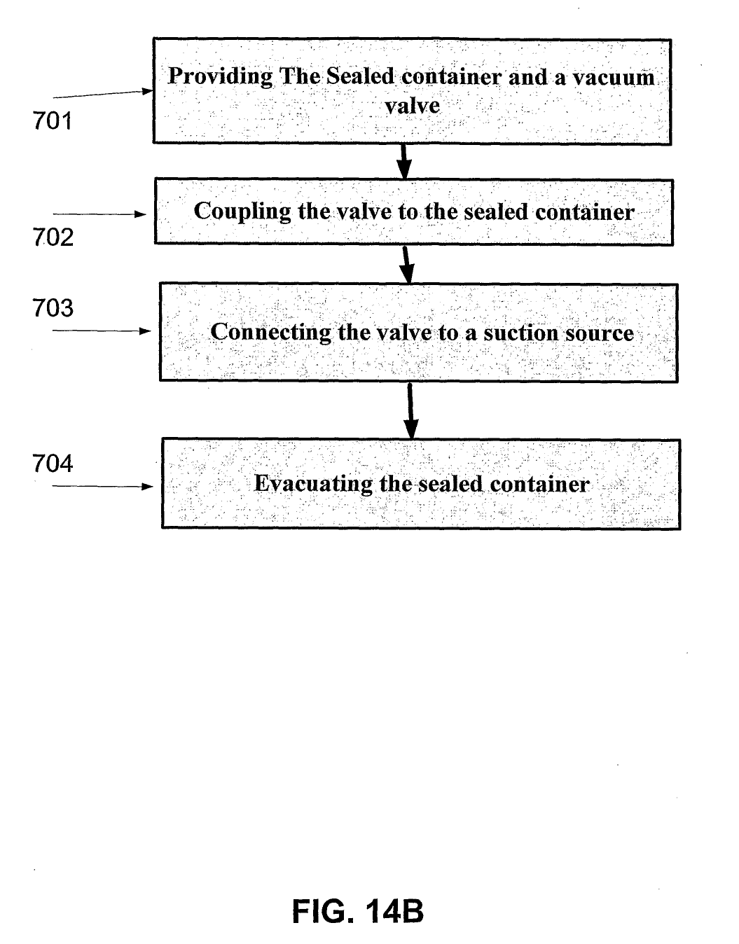

Reference is now made to FIG. 14A which depicts the vacuum valve and the linking fitting of FIG. 13. Parts that are the same as in previous figures are given the same reference numerals and are not described again. The vacuum valve and the vacuum thermal insulation panel and the vacuum valve are as in FIG. 13 however FIG. 14A depicts the linking fitting 110 without the screw-like pivot.

Reference is now made to FIG. 14B which is a flowchart of an exemplary method for producing an insulation panel with a vacuum valve according to a preferred embodiment of the present invention.

FIG. 14B depicts a method of producing sealed vacuum thermal insulation panels having a vacuum valve. The first step 701 is to provide a sealed insulation panel having a film substantially impermeable to atmospheric gases and water vapor, and further having an aperture and a permanent vacuum valve having a valve stopper. In the following step 702 the vacuum valve is overlaid to cover the aperture in the sealing.

In the following step 703 a source of vacuum suction is connected to a suction interface within the vacuum valve. The connection facilitates the next step 704 of evacuating the sealed insulation panel using the suction source to a predetermined level. Since the vacuum valve is coupled with a valve stopper with a default status of being closed, the disconnecting of the suction source does not impede the achieved predetermined vacuum level within the panel.

The disconnecting of the adaptor is carried-out in two steps. During the first step the pivot is lifted, thereby closing the vacuum valves. During the second step the vacuum pump is stopped, and the adaptor can than be disconnected from the vacuum insulation panel.

The present method produces insulation panels which can be easily re-evacuated through the vacuum valve as described above. The present embodiment also facilitates relatively easy repair of punctured panels. Punctured insulation panels, which are manufactured according to the present method can be sealably patched and re-evacuated through the permanent vacuum valve. Prior art insulation panels without a permanent vacuum valve cannot be easily re-evacuated since a designated orifice would have to be created for the evacuation process and to be sealed afterwards.

The repair of the insulation panel according to the preferred embodiment of the invention can be done without disassembling the panel from the insulation unit. Hence, the insulation panels can be fixed without delay, that is to say, without the requirement to move away the insulation panel from a particular insulation unit spot.

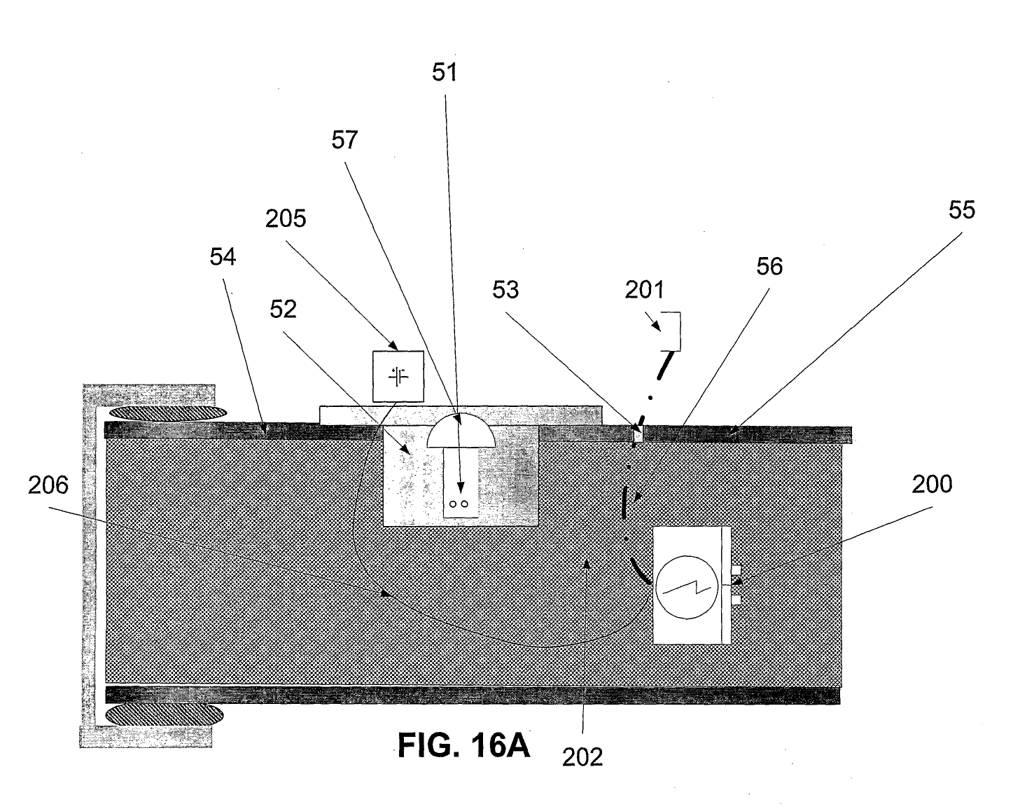

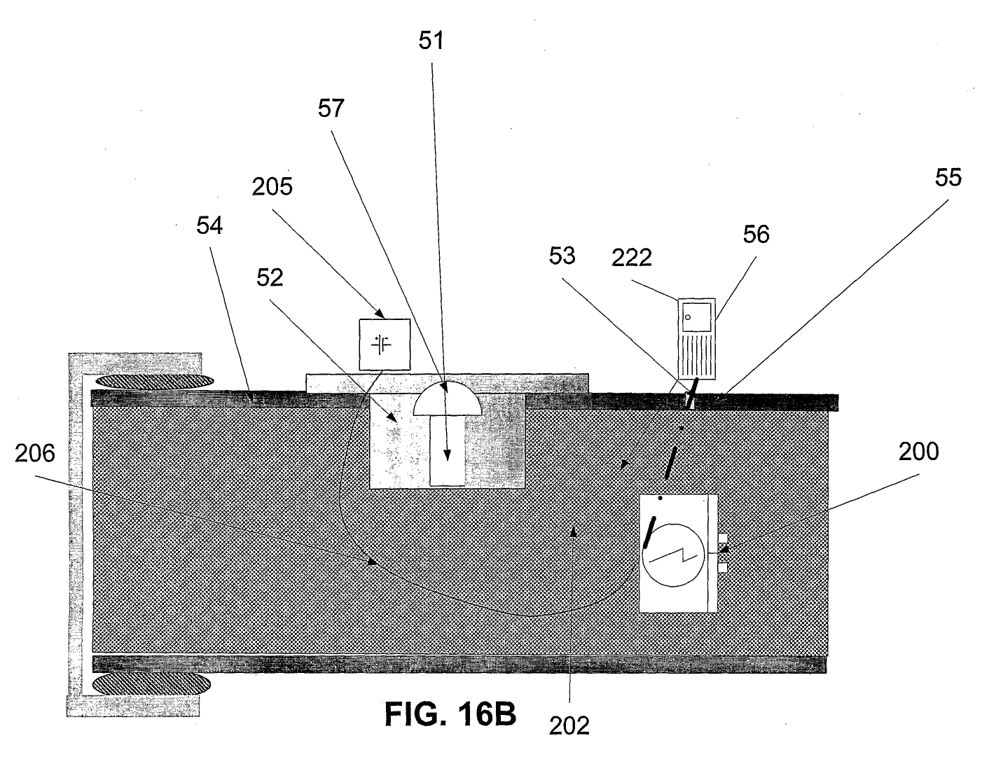

Reference is now made to FIG. 16A which depicts an exemplary sealed thermal insulation panel with a permanent vacuum valve and a pressure indicator. The panel, the vacuum valve and the aperture are as in FIG. 8 above, however, FIG. 16 further depicts a pressure indicator 200 being positioned within the sealed container 56, a spout 52 and a plug 201 positioned on the external side of the sealed panel on the proximity of the panel.

The sealed panel having a vacuum valve 51 provides the ability to maintain the pressure level within the panel, as described above, promising the capability to maintain a steady range of pressure levels.

However, no indicator is provided to maintenance personnel regarding if or when a re-evacuation of the panel is needed.

In the present embodiment, pressure indicator 200 is positioned within the sealed container 56. The pressure indicator 200 is inserted before the panel 56 is sealed or evacuated. The pressure indicator 200 is connected to a plug 201 which is positioned on the external side of the sealed panel 55. Preferably, the pressure indicator 200 is connected to the plug 201 through an orifice in the panel sealing 53. The plug 201 is designed for receiving information regarding the pressure level within the sealed panel 56 via, preferably, a line connection 202.

The combination of a vacuum valve 51 that facilitates the maintenance of the predetermined pressure level and an indicator 200 that notifies the maintenance person about an increase in predetermined range of pressure levels provides the maintenance person with the ability to maximize the utility of the panel's cooling potential in the long term.

Preferably, a power supply 205 for supplying the pressure indicator 200 with electrical current is coupled to the external side of the panel 54. The power supply 203 is connected to pressure indicator 200 via a line connection 206 through evacuation orifice 52.

Preferably, the plug 201 is connected to a LED diode. The LED diode indicates a decrease in pressure level according to the received information regarding the pressure level within the sealed panel 56 via the line connection 202.

Preferably, the plug 201 is connected to a screen, presenting the pressure level within the internal space of the panel.

Preferably, the plug 201 is connected to a central computer or to a central processor.

Since insulation panels are usually positioned in proximity to other panels, a central computer or processor can be used to gather information from more than one plug.

In one preferred embodiment of the invention the plug 201 is connected to a central computer as part of a maintenance system. Such a maintenance system can gather information from numerous panels from more than one insulation units. Such a maintenance system can preferably output the current status of each insulation panel at any given moment.

Preferably, the maintenance system facilitates the maintenance person with the ability to define a pressure threshold. Such a pressure threshold can be used to alarm the maintenance person when the pressure level in one of the insulation panels has decreased and should be re-evacuated to restore efficient thermal insulation.

Preferably, the maintenance system further comprises a screen display for displaying the current status of each insulation panel upon request.

In one preferred embodiment, the pressure indicator 200 is a piezoelectric device comprising a transducer (e.g. Rochelle salt Crystals). The piezoelectric device 200 measures the mechanical pressure on the transducer according to the charge the transducer produces when compressed. The piezoelectric device 200 produces a measurement of the pressure level according to the produced charge. The piezoelectric device 200 transmits the information regarding the pressure level via the line connection 202, to the plug 201.

In one preferred embodiment of the present invention the pressure indicator 200 comprises an induction heating element and a temperature detection element. The induction heating element is used for generating heat through electromagnetic induction by the action of a magnetic flux generator which is located in the proximity of the insulation panel.

The temperature detection element produces a measurement of the rate of thermal heat dissipation of inner space of the sealed insulation panel 51, and thereby a measurement of the pressure level within the sealed insulation panel 51.

Reference is now made to FIG. 16B which depicts another exemplary, vacuum thermal insulation panel with pressure indicator and permanent vacuum valve for maintaining the pressure level within the panel. The panel, the vacuum valve and the evacuation aperture are as in FIG. 16A above however, in FIG. 16B the line connection is connected to a processor 222 and not to a plug. In addition FIG. 16B depicts a pressure indicator 200 that comprises an electrical resistor 200 a heating element and a processor 222.

In this embodiment, the pressure indicator 200 is an electrical resistor, having a resistance which varies according to the temperature within the internal space of the insulation panel. In this preferred embodiment the power supply 205 supplies the heating element with electrical current to heat it to a predetermined temperature above that of the inner space temperature of the sealed container 56.

Preferably, the heating element and the electrical resistor 200 are coupled one to the other.

In addition, a processor for measuring the change in resistance of the electrical resistor 200 is connected to the electrical resistor 200 via a line connection 202. The processor 222 produces a measurement of the rate of thermal heat dissipation of the inner space of the sealed container 56 according to the measured change in resistance, and thereby a measurement of the pressure level within the sealed container 56. The processor 222 is positioned on the outside of the sealed container 56, wired to the electrical resistor 200 through an aperture in the container 53.

Preferably, the electric resistor is a thermistor.

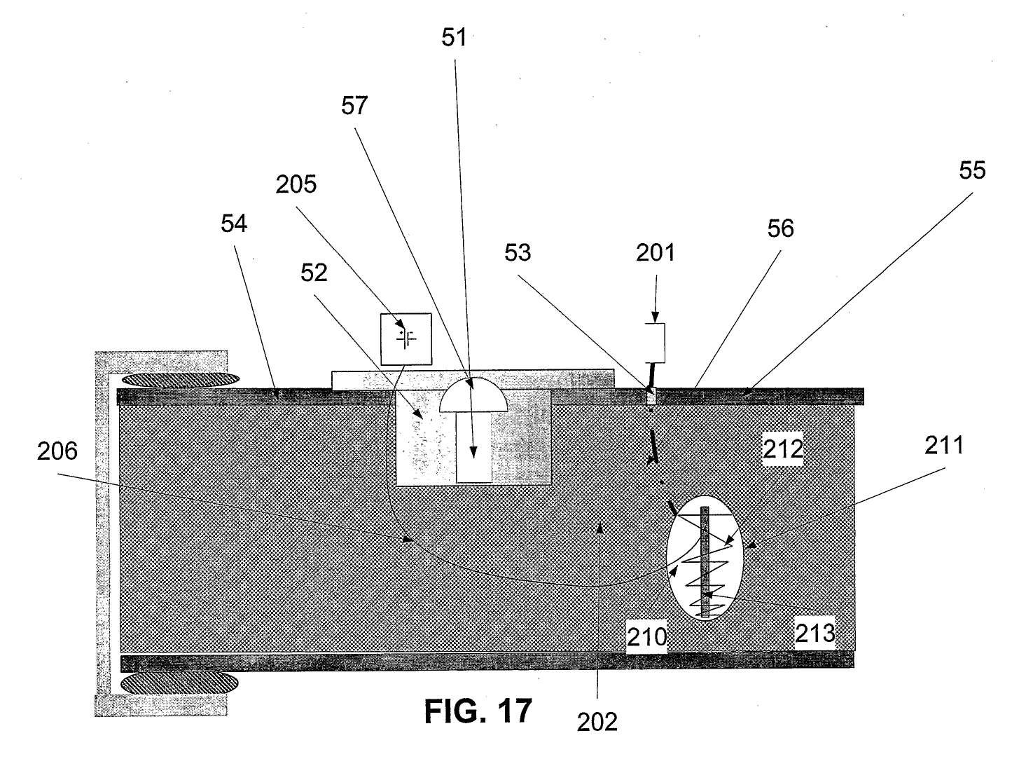

Reference is now made to FIG. 17 which depicts another exemplary, vacuum thermal insulation panel with pressure indicator and permanent vacuum valve for maintaining the predetermined pressure level within the panel. The panel, the vacuum valve and the evacuation aperture are as in FIG. 16A above however, FIG. 17 depicts a pressure indicator that comprises a pressure reference capsule 210.

In the present embodiment, the pressure indicator comprises a vacuum sealed pressure reference capsule 210 of a bending membrane. The pressure reference capsule 210 encloses a spring 211 that supports the inner walls of the pressure reference capsule 210 in such a manner that the bending of the sealed capsule affects the spring degree of compression.

The pressure reference capsule 210 is pre-evacuated to reach a predetermined pressure level which is lower than the pressure level of the insulation panel. The predetermined pressure level is used as a reference pressure level to the pressure level within the internal space of the panel 56. Since the capsule is hermetically sealed, it has a fixed pressure level which can be used as a reference pressure level.

When the pressure level in the internal space of the thermal insulation panel decreases, a substantial pressure difference between the capsule internal space and the panel's internal space is formed. The pressure difference causes the gas in the internal space of the panel to apply mechanical force on the capsule external membrane 211 in an attempt to regain equilibrium of pressures between the spaces. The applied mechanical force causes the capsule membrane 211 to bend. The bending of the membrane compresses the spring 212 within the capsule. The compressing of the spring 212 is detected by a compression detector 213 within the pressure reference capsule 210.

In one preferred embodiment of the present invention, the compression detector 213 is an electric circuit and the compression of the spring closes the electric circuit facilitating the passage of electricity in the circuit. The compression detector transmits information regarding the spring 212 status within the pressure reference capsule 210 via a line connection 215.

In another preferred embodiment of the present invention the compression detector is a laser-based distance detector located in the proximity of the vacuum sealed capsule 212. The laser-based distance detector measures the distance to the bending membrane 211 and produces a measurement of the curvature of the vacuum sealed capsule and thereby a measurement of the pressure of the sealed panel 56 internal space

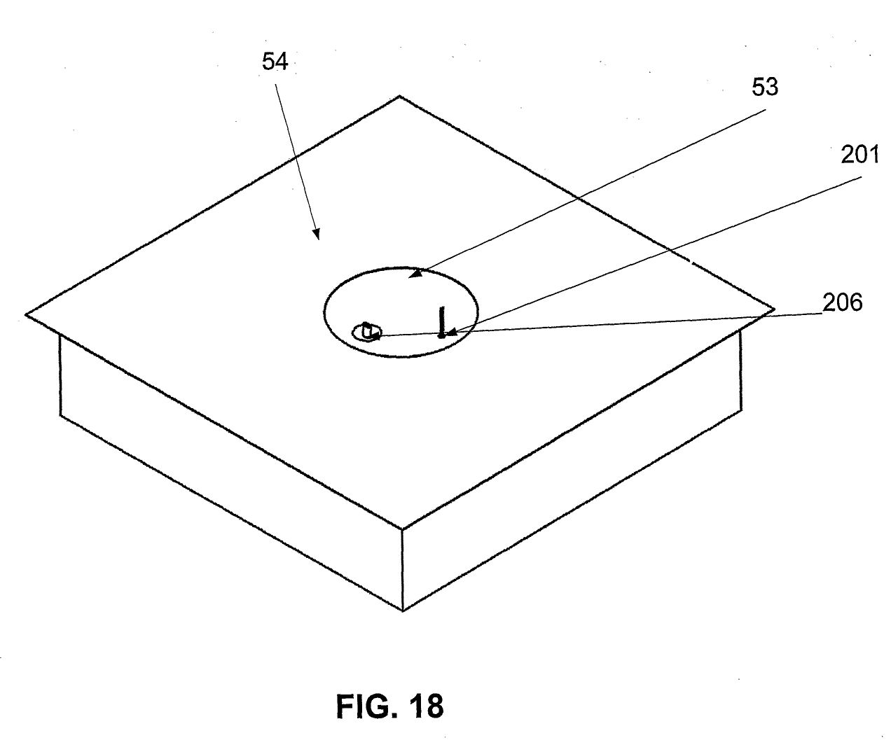

FIG. 18 is an external perspective view showing the plug 201 positioned on the external side of a panel wall 54 from the point of view of the top surface thereof. Preferably a power supply line connection 206 is connected through evacuation orifice 52.

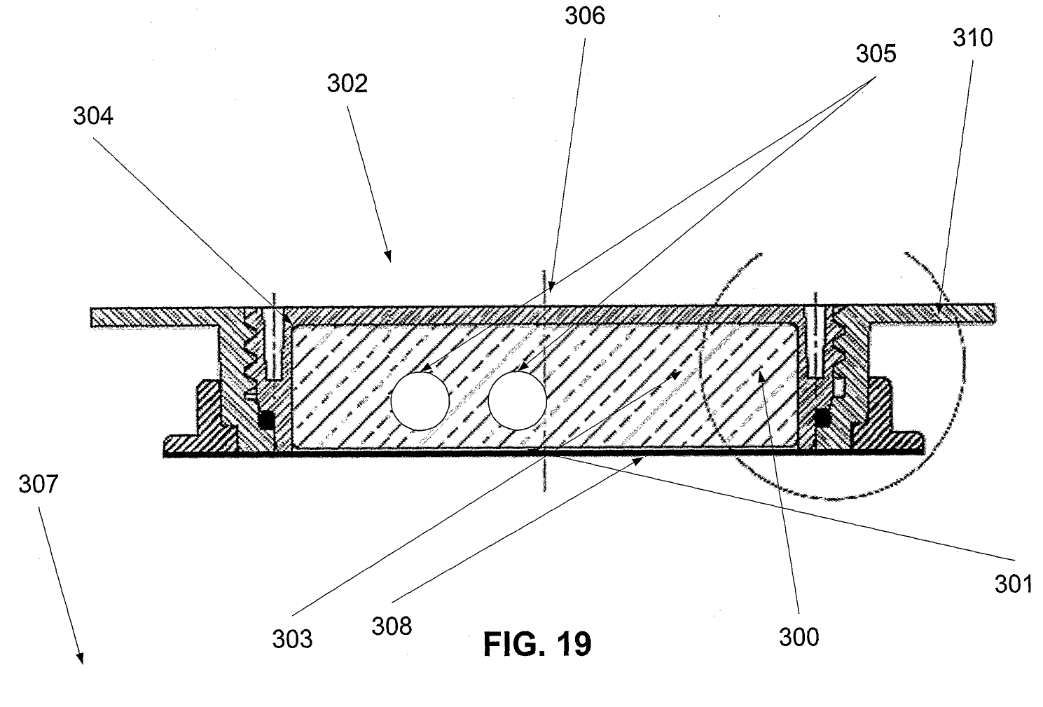

Reference is now made to FIG. 19 depicts an exemplary replacement device for replacing absorptive agents, a vacuum thermal insulation panel, according to a preferred embodiment of the present invention.

FIG. 19 depicts a sink shaped chamber 300, being positioned within an aperture 301 in the external sealing 302 of a vacuum thermal insulation panel, having a gas-permeable wall 303 and an evacuation aperture 304. The sink shaped chamber 300 contains absorbent agents 305. A removable cover 306 made of material substantially impermeable to atmospheric gases and water vapor overlies the aperture 301. The absorbent agents 305 comprises either desiccating agents for absorbing water and water vapors or getters to absorb gas molecules as a molecular sieves or to bind with gas molecules, thereby transferring them from the gaseous phase to the solid phase. The function of both getters and desiccating agents is explained above.

As described above with respect to FIG. 2, absorbent agents 305 are inserted into evacuated sealed containers in order to absorb penetrating gas molecules or to react with gas free molecules, thereby transferring them from the gaseous phase to the solid phase. Those chemical procedures prevent part of the gases from remaining in a free state in the evacuated sealed insulation panel. The absorbent agents 305, when active, absorb gas molecules, preferably by oxidizing any free oxygen molecule and reacting with nitrogen molecules in the panel, or by absorption as molecular sieves. These molecules are thus bounded to the solid phase and do not affect the pressure level within the panel.

However, the absorbent agents 305 have finite absorption capacity. Absorbent agents have a certain absorption capacity. Hence, absorbent agents 305 lose their effectiveness after they absorb or bind a certain amount of molecules.

The present embodiment facilitates the replacement of absorbent agents 305 after the vacuum thermal insulation panels are sealed and evacuated.

The replacement device 310 is placed within the panel, in proximity to the panel seals. The replacement device 310 covers an aperture 301 within the panel's external sealing 307.

The replacement device 310 further comprises a sink shaped chamber 300 for holding absorbent agents 305 and a removable cover 306 that seals the sink shaped chamber 300.

The sink shaped chamber 300 is designed to hold absorbent agents 305. In order to allow getters or desiccant agents to continue to absorb atmospheric gases from the internal space of the panel, an interface is provided that allows the passage of atmospheric gases between the chamber's internal space and the panel's internal space. Hence, the sink shaped chamber 300 comprises a semi-permeable wall 303 that facilitates the relatively slow diffusion of atmospheric gases between the aforementioned spaces at a low rate. The semi-permeable wall disposed between the chamber 300 and panel's internal space 308 is semi-permeable to gases but, preferably, impermeable to water and water vapors. Accordingly the moisture level within the panel's internal space does not rise when the chamber 300 is not sealed. Examples of suitable semi-permeable membranes with relatively slow diffusion include semi-permeable homopolymers or copolymers. For example, the semi-permeable membrane is made of polystyrene or silicone copolymers.

Moreover the semi-permeable film facilitates the efficient replacement of the getters and the desiccating agents. When the absorbent agents 305 are being replaced, the semi-permeable wall 303 is exposed to atmospheric gases and water vapors for a few seconds. Thus, some gases and water vapor do penetrate the internal space of the insulation panel through the semi-permeable wall 303. However, since the exposure duration is short and the semi-permeable wall 303 facilitates only low a diffusion rate, not many molecules pass via the semi-permeable wall 303.

Hence, when the plug is closed and absorbent agents 305 are in the chamber 300, the time interval during which molecules can freely diffuse into the absorbent agents' chamber 300 from the internal space of the panel 56 is much longer.

Thus, the quantity of molecules that are either absorbed or bound by the absorbent agents 305 when the chamber 300 is sealed is substantially higher than the quantity of molecules that penetrate the semi-permeable wall 303 when the chamber 300 is unsealed.

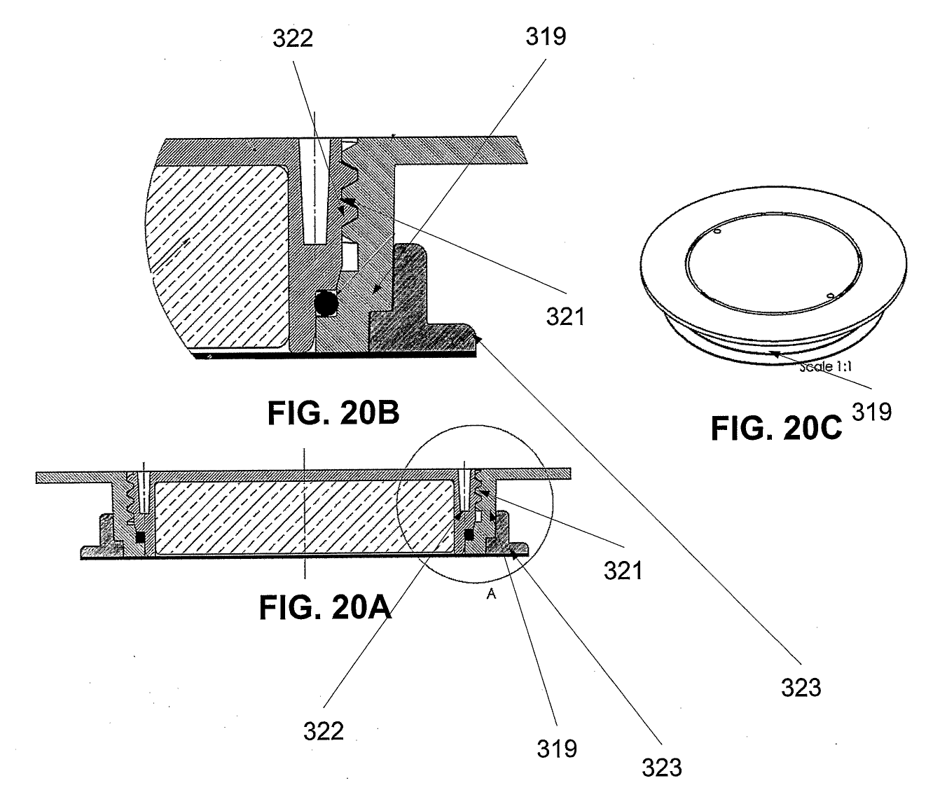

Reference is now made to FIGS. 20A, 20B, and 20C.

FIG. 20A is an intersection perspective view of the replacement device 310 positioned in a panel wall.

FIG. 20B is a close-up intersection perspective view of the junction between the valve's removable cover and the valve's chamber inner walls.

FIG. 20C is an external perspective view of the replacement device 310 showing the top surface thereof.

FIGS. 20A, 20B, and 20C depict a preferred embodiment of the absorbent agents replacement device according to the present invention. In this preferred embodiment, the sink shaped chamber's lateral walls 320 are coupled with internal screw thread 321 to be fitted onto a screw-like pattern coupled on the external lateral walls of the removable cover 322.

Preferably, the lateral walls 320 and the removable cover 322 are made from Barex®.

Preferably, semi-permeable wall 323 is made from polystyrene. Preferably an O-ring seal 323 is coupled to the chamber internal walls. The O-ring seal is situated in a groove 324 between the valve cover 302 and the valve's chamber 304, and compressed during assembly between them, thereby sealing the gap between the walls of the sink shaped chamber 304 to the cover 302.

Reference is now made, once again, to FIG. 19. The replacement device 310 according to one preferred embodiment of the present invention can solve an additional sealing problem.

Generally, during the manufacturing process of evacuated insulation panels, the internal space of the panels is evacuated using a source of vacuum suction through an evacuation aperture. However, in the duration the evacuation process, air and water vapor are still in relatively high rates within the panel's internal space. Hence, the absorbent agents actively absorb and react with the air and water vapor molecules.

Accordingly, absorbent agents exhaust some or all of their absorption potential even before the internal space of the insulation panel has been sealed to maintain the predefined pressure level.

In one preferred embodiment of the present invention, the evacuation of the panel's internal space is done through a permanent vacuum valve in the panel, as described above. During the evacuation of air from the insulation panel the air within the internal space of the vacuum is evacuated.

Since the semi-permeable wall 323 facilitates relativity slow diffusion of atmospheric gases between the sink shaped chamber 305 and the internal space of the insulation panel, atmospheric gases may remain in the sink shaped chamber 305 after the evacuation process of the insulation panel is finished.

Hence, preferably, in order to prevent the accumulation of atmospheric gases within the chamber 305, as described above, a filling is placed within the internal space of the chamber during the evacuation process.

Preferably, the filling is made of inert material as plastic. The filling is identically shaped as a gas absorbent agent capsule.

Moreover, the replacement device 310, according to the preferred embodiment of the present invention, facilitates the addition of absorbent agents 305 to the sink shaped chamber 300. Hence, absorbent agents 305 can be added after the evacuation process has ended. The positioning of absorbing agents in this stage of the process to leads to the removal of atmospheric gases from the internal space of the sink shaped chamber 300 and helps to maintain the achieved pressure level.

In addition, the present embodiment facilitates the maintenance of predetermined pressure level by the replacement of overused absorbent agents 305 during the life of the panel.

Preferably, the panel further comprises a pressure indicator, indicating the pressure level within the panel to maintenance personnel. Absorbent agents 305 can be replaced according to the pressure indicator.

Preferably, the pressure indicator is located within the panel, and is adapted to be connected via a line connection 309 through an aperture in the panel sealing to a plug or a display for transferring or displaying the pressure within the internal space of the panel.

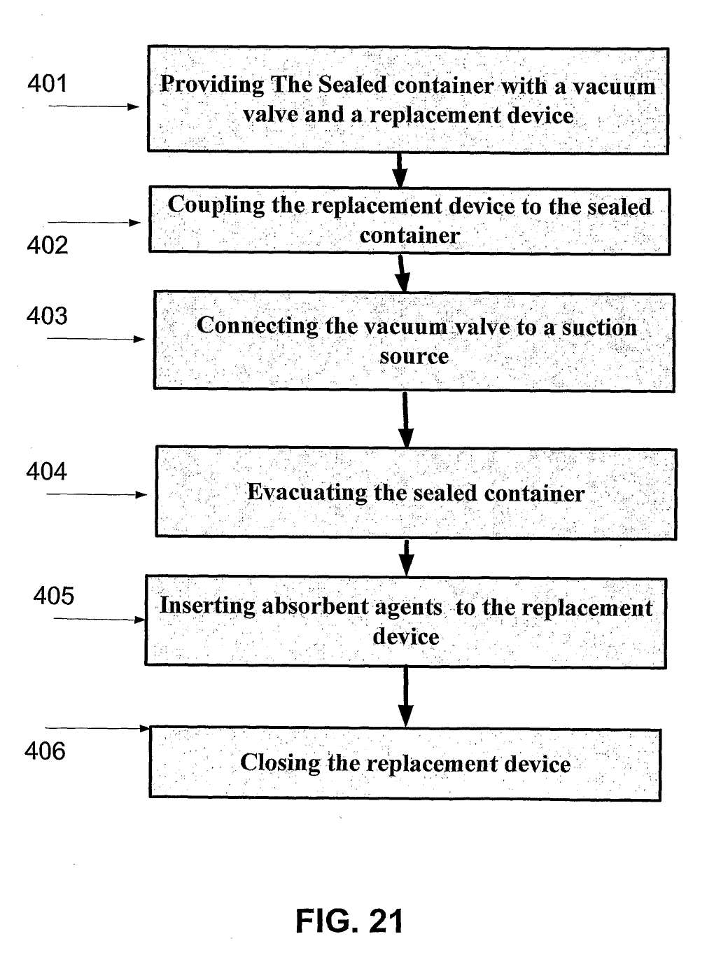

Reference is now made to FIG. 21, which is a flowchart of an exemplary method according to another preferred embodiment of the present invention. The method depicted in FIG. 21 follows the manufacturing steps of a sealed vacuum thermal insulation panel having an absorbent agents housing.

In the process, the first step 401 is to provide a sealed container of film substantially impermeable to atmospheric gases and water vapor having an aperture and a vacuum valve.

Additionally, during the first step 401a replacement device is provided. The replacement device is adapted to overlie the aperture in the sealed container. The replacement device comprises a sink shaped chamber with a wall which is semi-permeable to water vapor and to atmospheric gases and cover made of material substantially impermeable to atmospheric gases and water vapor, e.g. polymer with an Aluminum cover layer. The cover is designed to sealably cover the orifice of the sink shaped chamber, creating a sealed chamber.

Subsequently, in the next step 402, the replacement device is positioned in the sealed container's aperture. The aperture is used to connect a source of vacuum suction.

In the following step 403, the vacuum valve is connected to a vacuum source. Clearly the connection can be indirect, via an adaptor, or direct, via a vacuum pump. In the following step 404 the sealed container is evacuated of atmospheric gases and moisture using a vacuum source. In the next step 405, after disconnecting the suction source, absorbing agents are inserted to the sink shaped chamber. In the final step 406 the sink shaped chamber is sealed using the cover.

As described with reference to FIGS. 18 and 19, a panel with a replacement device, as manufactured according to the afore-described method, provides the ability to re-evacuate the internal space of the panel. These panels can maintain their vacuum level for long periods.

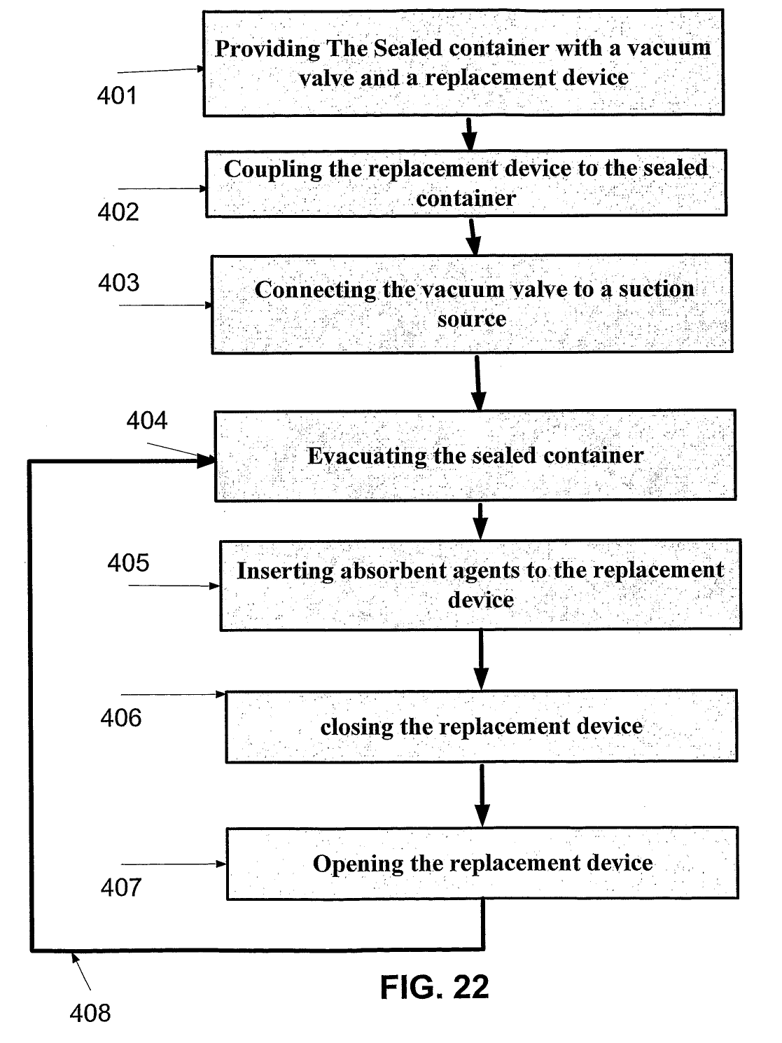

Reference is now made to FIG. 22, which is another flowchart of an exemplary method according to a preferred embodiment of the present invention. Steps 401-406 are as in FIG. 21 above however, step 407 and 408 are added. The method depicted in FIG. 22 follows the manufacturing steps of a sealed vacuum thermal insulation panel having an absorbents housing and the maintenance thereof. Step 407 depicts the re-Opening of the sink shaped chamber by removing the removable cover. And step 408 depicts the repetition in step 404-406, that is to say, the maintenance of the predetermined pressure level by adding new absorbent agents to the evacuated panel. As described above, one embodiment according to the present invention facilitates the replacement of absorbents in the panel. The replacement is carried out by removing the removable cover and replacing the absorbents.

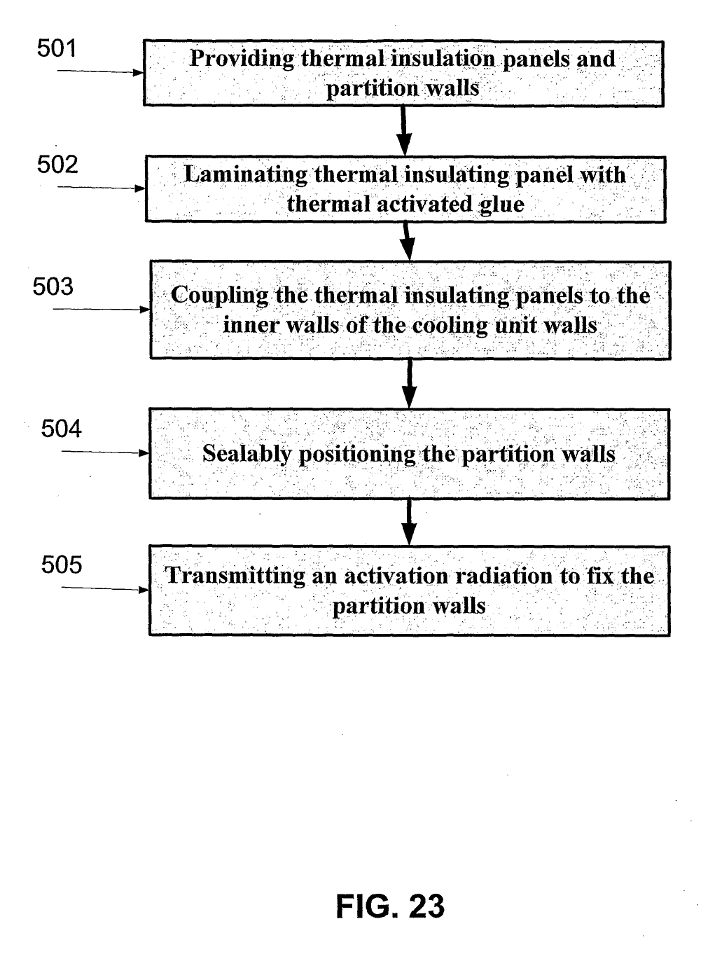

Reference is now made to FIG. 23, which is a flowchart of an exemplary method according to another preferred embodiment of the present invention. The method depicted in FIG. 23 follow the adhesion steps of a vacuum thermal insulation panel to a partition wall.

Thermal insulation panels are generally used in cooling rooms and insulation units as explained. Typically, in cooling rooms and insulation units' thermal insulation panels are positioned behind partition walls. The partition walls are used to protect the thermal insulation panels from damage. Other common motives to add a partition wall follow from design considerations.

For example, home refrigerator walls are typically coupled with an internal partition film which is designed to support the refrigerator's shelves.

During the manufacturing process, the insulation panel is positioned in-between an external partition wall, usually a metal case and an internal wall, usually a designed plastic case.

Since the inner partition walls are designated to coat the inner side of the insulation unit, the insulation panels may be laminated beforehand with an Adhesive layer adapted to attach the partition walls. During the positioning process of the partition walls, the walls may be glued to the inner side of the insulation units. However, laminating the panels with active adhesive before the insertion of the partition walls can hamper the positioning process, since, once the partition wall touches the active adhesive strip, the wall is immediately glued, preventing fine tuning of the positioning process.

Hence, it would be highly beneficial to have a method that facilitates the positioning of the films before the gluing action takes place.

Using adhesive foam can facilitate the gluing-after-positioning method. The adhesive foam is cured to fix the partition walls and the insulation panel only after the positioning of the panels in between the partition walls. However, the volume of the adhesive foam layer is relatively large. The volume of the insulation unit walls directly affects the effective capacity of the cooling storage volume.

Reference is now made to FIG. 23 which depicts a method for coupling insulation panels to partition films, which is devoid of the above mentioned volume disadvantage. Accordingly, the first step 501 is to provide thermal insulation panels and partition wall. Subsequently in step 502, the panel wall is laminated with layer of thermally activated adhesive. In this step the thermally activated adhesive is not activated and laminated as an additional external layer on the panel walls. Preferably, two opposite sides of the panel walls are laminated with a layer of thermal activated adhesive. During the next step 503, the insulation panels are coupled to the insulation unit internal walls. Preferably, the panels are coupled to the insulation unit internal walls in a manner such that the insulation unit's internal walls are completely covered. This hermetic cover provides effective insulation of the insulation unit. In the following step 504, the inner partition walls are positioned in the proximity of the insulation panels, forming a hermetic sealing that covers the panels. The positioning is preferably done at room temperature to prevent the premature activation of the thermally activated adhesive. As the thermal activated adhesive is not active at room temperature, the procedure does not hamper the positioning of the insulation panel and the partition walls.

During the next step 504, activation heat is provided to the ready-positioned arrangement. The heat activates the thermally activated adhesive, and thereby firmly attaches the thermal insulation panels with the partition walls.

One major advantage of this method is that the process is dry. Unlike the gluing of the insulation panel using liquidated adhesives, the use of thermally activated adhesives promises the fixation of the insulation panel in a dry surrounding. Hence, the machinery which is used in the process does not have to be liquid-enhanced.

Preferably, the heat activates the layer of thermally activated adhesive on the panel wall that approaches the insulation unit internal walls firmly attaches the thermal insulation panels with the insulation unit internal walls.

Preferably, the layer of thermal activated adhesive is activated by RF radiation. In this embodiment the wall of the insulation unit is made of a transparent RF radiation material.

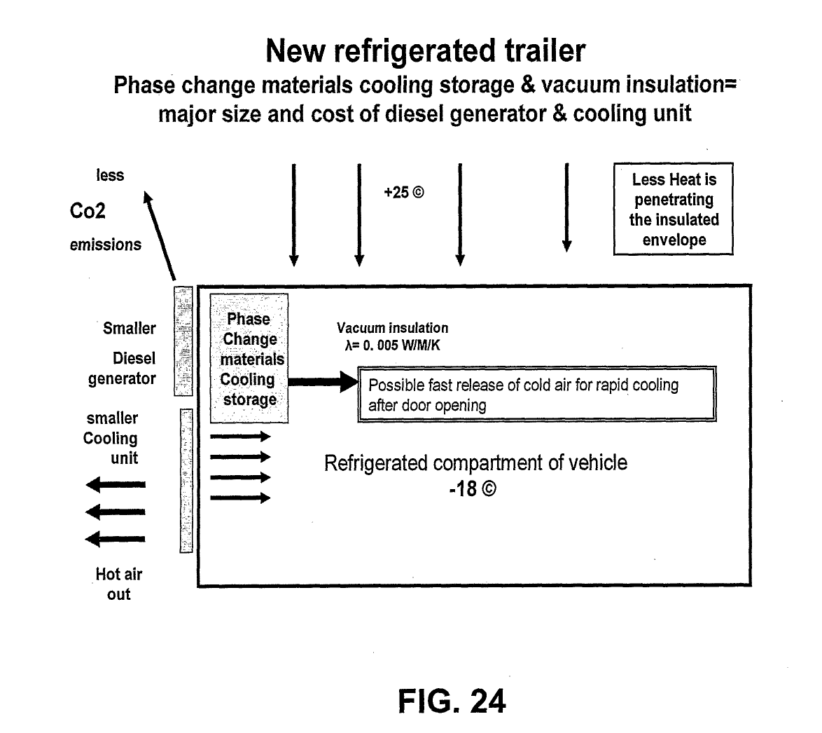

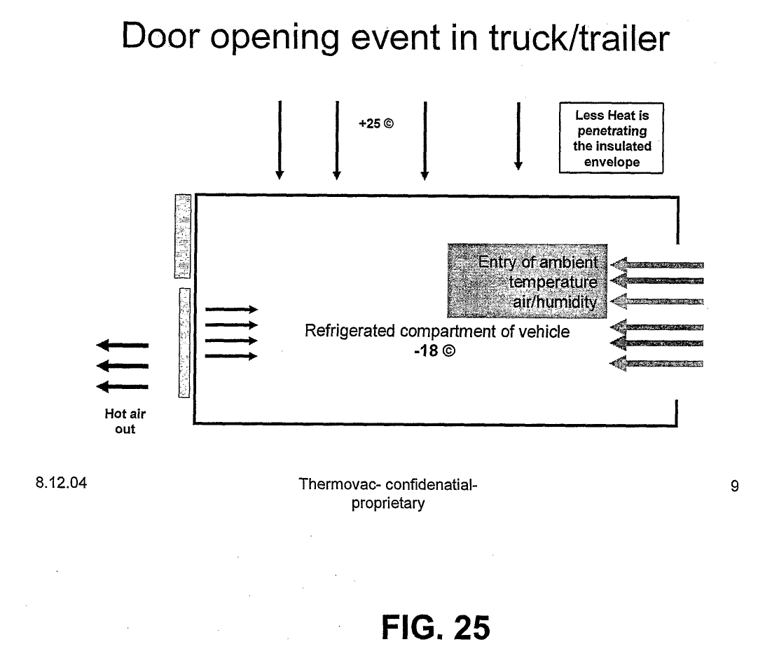

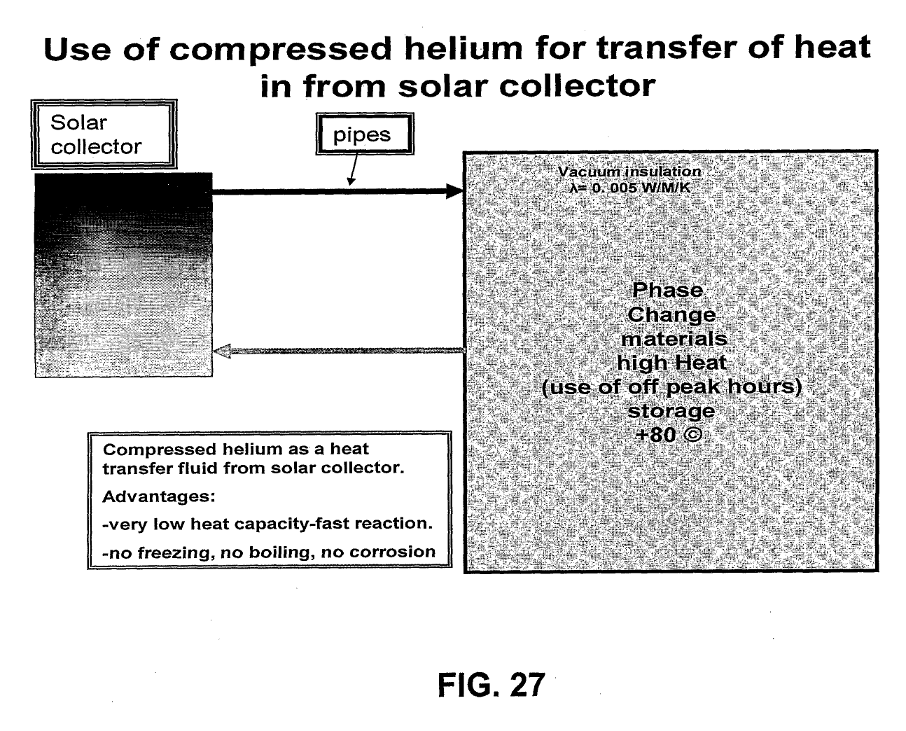

Reference is now made to FIGS. 24 and 27 which depicts an exemplary, sealed insulation unit for refrigerated vehicles according to a preferred embodiment of the present invention.

Vacuum insulation panels facilitate better thermal insulation than non-evacuated insulation panels which are commonly used in refrigerators, freezers, vehicles, hot water storage and buildings.

As described above, thermal conductivity of vacuum insulation panels is typically 4-12 times better than non-evacuated insulation panels such as insulation panels of foamed insulation materials. The improved resistance to heat can permit the creation of insulation panels which are relatively thinner than without the improved resistance to heat. Such insulation panels are well adapted to fit refrigerated vehicles' containers (e.g. trucks' containers, ships' containers, trains' containers or air-borne containers) as the overall dimensions of the truck are restricted and so increased insulation thickness reduces the usable volume and thus the functionality of the truck storage space.

For example, in a typical European setting, refrigerated vehicles have a standard width which is determined by the regulator. Hence, the outer dimension of the truck is determined. Thus, in this embodiment, better insulation is achieved in such fixed thickness walls.

In addition, the prices of energy sources in the last years rise. Hence, there is a requirement to improve the utilization of each energy unit's potential.

Accordingly, both a thinner insulation panel with better thermal resistance is needed.

Such an effect can be achieved using vacuum insulation panels. The use in such panels reduces the average energy consumption.

In addition, another possible advantage of the aforementioned insulation panels is that they reduce the capacity of the cooling units that are currently used for trucks and trailers.

Using vacuum insulation panel can reduce the cooling unit size.

Moreover, the usage of a vacuum insulation panel can eliminate or reduce the need in an independent engine to consume relatively high amounts of energy.

The integration of insulation panels into refrigerated vehicles walls creates an efficient system that can be highly beneficial for truck manufacturers and possessors, decreasing the maintenance cost of each refrigerated vehicle.

However, the aforementioned integration has some obstacles.

If the doors of the insulation unit of the refrigerated vehicle are opened, the air from the outer surrounding can penetrate the internal space of the insulation unit.

If the air from the outer surrounding penetrates in to the internal cooling space of the truck's container, a substantially large amount of energy will be needed to restore the required cooling temperature within the insulation unit.

Hence, this penetrating air must be cooled quickly as possible. In addition, water vapors which penetrate into the cooling space increases the moisture rate within the cooling space and thereby places an additional burden on the cooling unit.

The presently described embodiment of the present invention describes a system which was designed to overcome the aforementioned disadvantages. The system according to the preferred embodiment of the present invention comprises a cooling storage system, a refrigerated drying system, or both.

Since the duration in which the doors of the insulation unit are opened is usually relatively short, it will highly beneficial to have an additional fast cooling unit which stores cooled solid or liquid which can release cool air after the event of opening of the insulation unit's doors. An example for fast cooling units is a unit cooled by eutectic unit or a unit cooled by phase change (PCM) materials.

Preferably, the additional fast cooling unit uses the truck main engine as an energy source. The eutectic or PCM unit can be recharged during the relatively long intervals the doors are closed, and be used in the short intervals of door opening.

The advantage of such a system is that the additional fast cooling unit is activated during the time interval the refrigerated vehicles doors are opened.

The additional fast cooling unit does not consume more energy or cooling capacity during the time interval the refrigerated vehicles doors are opened or as an outcome of the doors opening in order to restore the cooling level after the refrigerator doors are opened. Additionally, less additional cooling is needed from the main insulation cooling unit to restore the cooling level in the insulation unit internal space.

In another preferred embodiment of the invention desiccating agents are used. A significant portion of the energy needed to cool penetrating air in the event of door opening is air drying. Since the air temperature declines, the absolute humidity declines as well, and water vapors condense.

The energy which is needed for this condensing and cooling is dependant on the relative percentage of water vapor in the surroundings.

It is possible to add to the insulation unit of the vehicle desiccating agents which are activated upon door opening and onward and thus reduce the energy needed to achieve and maintain a predetermined temperature level within the container. Since desiccating agents have the tendency to become exhausted after a while, the desiccating agents may be regenerated. Lithium Chloride, molecular sieve, Calcium Chloride, Clay and others can be used to as desiccating agents. The regeneration process is generally done by heat.

The combination of cooling storage and air drying with containers insulated by vacuum panels has many advantages as described above.

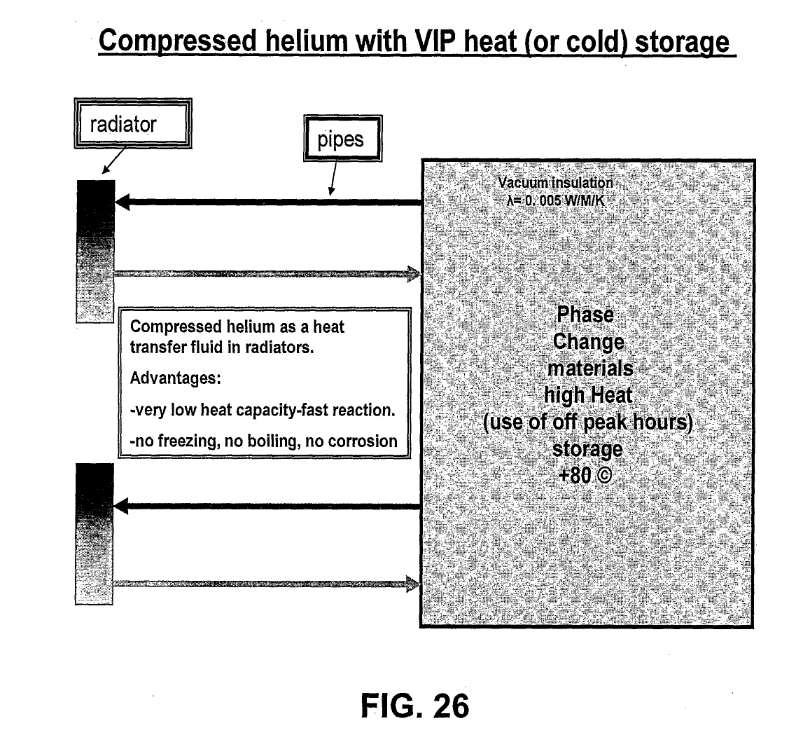

Reference is now made to FIGS. 26 and 29 which depicts an exemplary, sealed insulation unit that integrates a system that uses compressed Helium for cooling and heating according to a preferred embodiment of the present invention.

In another preferred embodiment of the invention compressed Helium is used. In many cases the refrigerated container truck, marine container etc. are independently cooled by an electric engine.

In this preferred embodiment the cooling units are linked to at least one other source of cooling conductive agent. One cooling conductive agent is compressed Helium, a fluid with very high heat transfer capacity, that does not freeze in the temperature range used. The Helium shortens the time period for transferring heat from the containers to a central unit.

In one preferred embodiment the Helium based system is integrated into marine transportation containers with insulation units which are fed by the boat power supply. Compressed Helium pipes are integrated into the marine transportation containers and transfer heat from a central insulation unit to each marine transportation container. Since in this preferred embodiment such marine transportation container does not integrate an independent cooling engine, the usage of such a system can utilize more effectively the capacity of the containers.

It should be noted that regular cooling containers have independent engines and independent heat exchangers. Hence, a separating space between the regular cooling containers is required for facilitating heat release from the engines and the heat exchangers. Since the containers according to the present invention, do not require contentious operation or even have an independent engine and independent heat exchanger. They can be positioned in proximity to one another, without any separating space between them.

In one embodiment, desiccating agents may be used in a domestic refrigerator, container or a freezer.

In another preferred embodiment, phase changing materials are used in domestic refrigerators and freezers to store or absorb thermal energy. These may be provided in combination with regenerated desiccating agents.

As elaborated above the usage in vacuum insulation panels reduces the required capacity of the cooling unit.

Hence, some of the saved capacity can be used for cooling a thermal storage agent. For example, a refrigerator or a freezer can be programmed to cool the internal cooling space and to cool a thermal storage agent during low electricity tariff periods as cool storage. In such a refrigerator or a freezer the cooled thermal storage agent absorbs heat during the high electricity tariff periods.

Accordingly the electricity consumption during the time the electricity rate is high may be reduced.

The cooled thermal storage agent can also be used as a backup for internal space of a refrigerator to provide cooling during a failure of the electricity supply. It is also possible to design a freezer with a smaller cooling unit.

One advantage of such a system is that since the system is active only during a limited time period of the day, it is quieter during the non-active time frame.

In addition, the vacuum insulation panels constitute a better insulation and therefore, less energy is needed to maintain the predetermined temperature within the cooling unit.

Moreover the use of vacuum insulation panels facilitates the use of thinner panels to achieve the same insulation effect. Thinner panels facilitate either the enlargement of the storage area or the hosting of more phase change materials (PCM) within the cooling unit.

Another preferred embodiment of the invention relates to hot water storage. Storing hot water with phase change materials (PCM) can save space or store more heat in the same space. Combining hot water storage, PCM and vacuum insulation may again take advantage of off peak electricity. The concept may be combined with solar energy.

It is expected that during the life of this patent many relevant devices and systems will be developed and the scope of the terms herein, particularly of the terms welding materials, sealing material, material substantially impermeable to atmospheric gases and water vapors, getters, desiccating agents are intended to include all such new technologies a priori.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents, and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

What is claimed is:

1. A sealed panel for vacuum thermal insulation, the panel having a thermal barrier, the panel comprising:
a core made of thermal insulation material;
a first and a second panel wall, each made of a first barrier material substantially impermeable to atmospheric gases and water vapor, said first and second panel walls respectively having an obverse and a reverse sides, said reverse sides respectively covering opposite sides of said core;
at least one lateral strip comprising a second barrier material substantially impermeable to atmospheric gases and water vapor, said lateral strip having an internal and an external side, said lateral strip being adapted to sealably enfold the edges of said obverse side of said first and second panel walls; and
at least one first sealing strip comprising sealing material, said first sealing strip adapted to sealably join said edges to said internal side of said lateral strip.

2. The sealed panel of claim 1, wherein said first sealing strip is laminated on said obverse sides of side first and second panel walls respectively.

3. The sealed panel of claim 1 or claim 2, further comprising a second sealing strip, said second sealing strip being laminated on said internal side of said lateral strip.

4. The sealed panel of claim 1, wherein a thermal conductivity of said second barrier material is lower then the thermal conductivity of said first barrier material.

5. The sealed panel of claim 1, wherein said first barrier material and said second barrier material are made from the same material.

6. The sealed panel of claim 1, wherein one of or both said obverse said of said first and second panel walls and said external side of said lateral strip further comprises a coating layer having a relatively lower thermal conductivity than Aluminum.

7. The sealed panel of claim 6, wherein said coating layer consists of at least one of the following materials: Polyethylene, Polyethylene teraphtalate (PET), Polyvinylidene Chloride (PVDC), Polychlorotrifluoroethylene (PCTFE), Cyclic Olefin Copolymer, Polypropylene, Liquid Crystal Polymer, Silicon Oxide, Aluminum oxide and metal film.

8. The sealed panel of claim 1, further comprising at least one desiccating agent located in-between said first and second panel walls.

9. The sealed panel of claim 1, further comprising getters located in-between said first and second panel walls.

10. The sealed panel of claim 1, wherein said first sealing material consists of at least one of the following sealing materials: a rubber-modified acrylonitrile copolymer, a thermoplastic resin (PVC), Liquid Crystal Polymers (LCP), Polyethylene teraphtalate (PET), Polyvinylidene Chloride (PVDC), and Polyvinylidene Chloride mixed with Polychlorotrifluoroethylene (PCTFE).

11. The sealed panel of claim 1, wherein said core consists of at least one of the following materials: pyrogenic silicic acid, polystyrene, polyurethane, glass fibers, perlite, open cell organic foam, precipitated silica, and fumed silica.

12. The sealed panel of claim 1, wherein said first sealing material is blended with nano-composites of clay.

13. The sealed panel of claim 1, wherein said first sealing material is blended with flame-retardants.

14. The sealed panel of claim 1, wherein said lateral strip comprises an alloy consisting of at least one of the following materials: Titanium, iron, nickel, cobalt, and stainless steel.

15. The sealed panel of claim 1, wherein said first sealing strip is a dual layer strip comprising:
an internal layer of one of a first material substantially impermeable to atmospheric gases and a second material substantially impermeable to water and water vapor; and
an external layer of the other of said first material and said second material, wherein said external layer sealably covers said internal layer.

16. The sealed panel claim 15, wherein said first material is rubber-modified acrylonitrile copolymer; wherein said second material is polyethylene.

17. The vacuum thermal insulation panel of claim 1, wherein said first barrier material consists of at least one of the following materials: non ferrous metal and Alloy comprising at least one non ferrous metal.

18. The vacuum thermal insulation panel of claim 1, wherein one or both said first and a second panel walls and said lateral strip are a laminate, wherein said laminate consists at least one of one layer of the following layering materials: Polyethylene teraphtalate (PET), Polyethylene Naphthalate (PEN), Cyclic Olefin Copolymer (COC), Liquid Crystal Polymers (LCP), Polyvinylidene Chloride (PVDC), and barrier adhesive like PVDC.

19. A sealed panel for evacuated thermal insulation, comprising:
a first sealing strip comprising a first sealing material being characterized by a first predetermined impermeability to gases and by a second predetermined impermeability to water vapors, wherein said first predetermined impermeability is higher than the impermeability to gases of High-Density Polyethylene and said second predetermined impermeability is lower than the impermeability to water vapors of High-Density Polyethylene; and
at least one desiccating agent.

20. The sealed panel of claim 19 wherein said first sealing material is rubber-modified acrylonitrile copolymer.

21. The sealed panel of claim 19 further comprising:
a core made of thermal insulation material;
a first and a second panel wall respectively made of a first barrier material substantially impermeable to atmospheric gases and water vapors, said first and second panel walls having obverse and a reverse sides respectively, wherein said reverse sides of said first and second panel walls respectively cover opposite sides of said core; wherein said first sealing strip being positioned to sealably join the edges of said reverse sides of said first and a second panel walls.

22. The sealed panel of claim 21, wherein said first sealing strip is laminated on said obverse side of side first and second panel walls.

23. The sealed panel of claim 21, further comprising at least one lateral strip comprising a second barrier material substantially impermeable to atmospheric gases and water vapors, said lateral strip being adapted to sealably enfold the edges of said obverse side of said first and second panel walls.

24. The sealed panel of claim 23, wherein said second barrier material conductivity is lower then the thermal conductivities of said first barrier material.

25. The sealed panel of claim 19, wherein said first sealing material is blended with nano-composites of clay.

26. The sealed panel of claim 19, wherein said first sealing material comprises blended flame-retardants.

27. The sealed panel of claim 19, wherein said first sealing strip is laminated with a second sealing strip comprising of material being characterized by impermeability to water vapors which is higher than the impermeability to water vapors of High-Density Polyethylene substantially impermeable to water and water vapor.

28. A method of producing sealed vacuum thermal insulation panels, comprising the following steps:
a) providing a core of thermal insulation material;
b) providing a first and a second panel wall of a first material substantially impermeable to gas and water vapor, said first and a second panel having an obverse and a reverse sides,
c) positioning said reverse sides of said first and second panel walls to respectively cover opposite sides of said core;
d) providing at least one lateral strip of a second material substantially impermeable to gas and water vapor, said lateral strip having an external and an internal side;
e) laminating the obverse sides of said first and second panel walls with a first coating layer of a sealing material; and
f) sealably enfolding the edges of said obverse sides of said first and second panel walls using said internal side of said lateral strip.

29. The method of claim 28, further comprising a step between step “b” and “c” of laminating the reverse sides of said first and second panel walls with an adhesive layer of an adhesive material.

30. The method of claim 28, further comprising a step between step “d” and “e” of laminating the internal side of said lateral strip with a second coating layer of said sealing material.

31. The method of claim 28, further comprising a step between step “b” and “c” of laminating the reverse sides of said first and second panel walls with an adhesive layer of an adhesive material.

32. The method of claim 28, wherein said step f) further comprises leaving an unsealed aperture between the edges of said obverse sides of said first and second panel walls and said lateral strip; further comprises the following step:
g) connecting a suction source to said aperture;
h) evacuating atmospheric gases, water and water vapors via said aperture; and
i) sealing said aperture.

33. The method of claim 28, wherein said sealing material comprises at least one of the following sealing materials: adhesive rubber-modified acrylonitrile copolymer, Polyvinylchloride, Saran polyvinylidene chloride, Liquid Crystal Polymers, Polyethylene, Polypropylene, polyethylene terephthalate and cyclic olefin copolymer.

34. The method of claim 28, wherein said second material conductivity is lower then the thermal conductivities of said first material.

35. The method of claim 28, wherein said lateral strip is made of material with lower thermal conductivity then the thermal conductivity of said first and second panel wall.

36. The method of claim 28, wherein said sealing is done by transmitting RF radiation on said coating layer, via said lateral strip.

37. The method of claim 28, wherein said sealing is further done using a roller being adapted to apply pressure on said coating layer in the tangent area of said lateral strip and the edges of said obverse sides of said first and second panel walls.

38. The method of claim 37, wherein said sealing is further done by transmitting RF radiation on said coating layer, via said lateral strip.

39. The method of claim 28, further comprising the step between step “e” and “f” of positioning at least one desiccating agent in-between said first and second panel wall.

40. The method of claim 28, wherein said sealing material is one of a first sealing material substantially impermeable to atmospheric gas and a second sealing material substantially impermeable to water and water vapor; further comprising a step between steps “e” and “f” of covering said coating layer with an additional coating layer, said additional coating layer being made of the other of said first sealing material and said second sealing material.

41. The method of claim 40, wherein said substantially impermeable to water and water vapor sealing material is Polychlorotrifluoroethylene (PCTFE).

42. The method of claim 28, wherein said sealing material consists at least one of the following sealing materials: a rubber-modified acrylonitrile copolymer, a thermoplastic resin (PVC), Liquid Crystal Polymers (LCP), Polyethylene teraphtalate (PET), and Polyvinylidene Chloride mixed with Polyvinylidene Chloride (PVDC), Polyethylene, Polypropylene, Cyclic Olefin Copolymer, Polyethylene Naphthalate (PEN).

43. An evacuated insulation panel with an instrument for maintaining a predetermined pressure level thereof, comprising:
a sealed insulation panel comprising a film of material substantially impermeable to atmospheric gases and water vapor;
an evacuation orifice provided in said sealed insulation panel;
an instrument for maintaining predetermined pressure level, said instrument comprising:
a vacuum valve having a valve stopper positioned to overlie said evacuation orifice, being positioned partly within said sealed insulation panel, partly on the outer surface of said sealed insulation panel, said valve default status being closed,
a suction interface located in the proximity of said valve stopper, said suction interface adapted to be connected to a source of vacuum suction.

44. The evacuated insulation panel of claim 43, wherein said suction interface being further adapted to be connected to an adaptor of said source of vacuum suction.

45. The evacuated insulation panel of claim 43, further comprising a spout substantially forming a valve tube with an open first end and an open second end, wherein said vacuum valve being positioned within said valve tube, said spout overlies said evacuation orifice.

46. The evacuated insulation panel of claim 45, wherein said spout is made of material substantially impermeable to atmospheric gases.

47. The evacuated insulation panel of claim 46, wherein said spout comprises an compressed or injected rubber modified Acrylonitrile.

48. The evacuated insulation panel of claim 43, wherein said vacuum valve comprises:
a sink shaped chamber having at least one aperture and a valve stopper;
a spring recess located in said sink shaped chamber;
a spring adapted to be threaded on said recess, pressing said valve stopper toward said evacuation orifice, said spring being adapted to maintain said vacuum valve closed when released or open when pressed by said valve stopper.

49. The evacuated insulation panel of claim 43, wherein said vacuum valve further comprises a vacuum valve plug, said vacuum valve plug being adapted to be removably connected to said valve stopper; said vacuum valve plug being adapted to prevent said valve stopper movement when plugged.

50. The evacuated insulation panel of claim 43, further comprising a linking fitting adapted to be connected to said vacuum valve via said suction interface, said linking fitting being adapted to transfer suction pressure between said vacuum valve and a suction apparatus or an adaptor thereof, said linking fitting having an integrated tube operable for facilitating access to said valve stopper.

51. The evacuated insulation panel of claim 43, further comprising:
a pressure indicator being positioned within said sealed insulation panel; and
a plug positioned on the external side of said sealed insulation panel, connected to said pressure indicator through an orifice in said sealed insulation panel, operative for receiving information regarding the pressure level within said sealed insulation panel via said connection.

52. The evacuated insulation panel of claim 43, further comprising:
an electrical resistor having a resistance varying with temperature to be positioned within said sealed insulation panel;
a power supply for supplying said electrical resistor with electrical current to heat it to a predetermined temperature above the temperature of the inner space of said sealed insulation panel, said power supply is connected to said electrical resistor through an orifice in said sealed insulation panel; and
a processor for measuring changes in resistance of said electrical resistor is used to produce a measurement of the rate of thermal heat dissipation of inner space of said sealed insulation panel, and thereby a measurement of the pressure level within said sealed insulation panel, said heat processor is positioned o the outside of said sealed insulation panel, wired to said electrical resistor through said evacuation orifice.

53. The evacuated insulation panel of claim 52, wherein said electric resistor is a thermistor.

54. The evacuated insulation panel of claim 43, further comprising:
an induction heating element for generating heat through electromagnetic induction by the action of magnetic flux generated by a magnetic flux generator adapted to be positioned in the proximity of the insulation panel, said induction heating element being adapted to be positioned within said sealed panel; wherein said pressure indicator is a temperature detection element for operable to produce a measurement of the rate of thermal heat dissipation of inner space of said sealed insulation panel, and thereby a measurement of the pressure level within said sealed insulation panel.

55. The evacuated panel of claim 51, wherein said pressure indicator comprises:
a vacuum sealed capsule of a bending membrane enclosing a spring supporting the walls of said vacuum sealed capsule in a manner that the bending of said sealed capsule affects said spring degree of compression; and
a compression evaluator operable for measuring the spring compression to produce a measurement of said vacuum sealed capsule curvature, and thereby a measurement of the pressure level of said sealed insulation panel, said compression evaluator operative for transmitting said information to said plug according to said measurement.

56. The evacuated panel of claim 51, wherein said pressure indicator comprises:
a vacuum sealed capsule of a bending membrane;
a laser-based distance detector located in the proximity of said vacuum sealed capsule, operable for measuring the distance between said laser-based distance detector and said bending membrane to produce a measurement of said vacuum sealed capsule curvature, and thereby a measurement of the pressure of said sealed insulation panel, said pressure indicator operative for transmitting said information to said plug according to said measurement; and
a power supply for supplying said laser-based distance detector with electrical current, connected to said laser-based distance detector through an aperture in the panel sealing.

57. The evacuated panel of claim 51, wherein said pressure indicator comprises:
a piezoelectric device being positioned within said sealed insulation panel, operable for measuring the mechanical pressure on said piezoelectric device to produce a measurement of a pressure level, and thereby to turn said mechanical pressure into a voltage representing the said pressure level, said pressure indicator transmit said information according to said voltage;
a power supply for supplying said piezoelectric pressure sensing device with electrical current, connected to said piezoelectric pressure sensing device through said evacuation orifice.

58. The evacuated panel of claim 43, further comprising a thermal insulation material vacuum packed within said sealed insulation panel.

59. The evacuated panel of claim 58, wherein said thermal insulation material consists of at least one of the following materials: pyrogenic silicic acid, polystyrene, polyurethane, glass and mineral fibers, perlite, open cell organic foam, fumed silica, and precipitated silica.

60. The evacuated panel of claim 43, wherein said film being substantially impermeable to atmospheric gases and water vapor comprises at least one of the following materials: non ferrous metal and Alloy comprising at least one non ferrous metal.

61. The evacuated panel of claim 43, wherein said vacuum valve further comprises:
a sink shaped chamber having at least one gas-permeable wall and an evacuation aperture, said chamber being operative for holding getters and desiccating agents; and
a removable cover of material substantially impermeable to atmospheric gases and water vapors, said cover designed to sealably overlie said sink shaped chamber, said cover being adapted to be connected to said valve stopper.

62. A vacuum valve for maintaining predetermined pressure levels in sealed insulation panels, comprising:
a sink shaped chamber adapted to overlie an evacuation aperture in sealed insulation panels, sink shaped chamber having an evacuation orifice,
a valve stopper adapted to overlie said evacuation orifice, said valve stopper being adapted to be positioned on the outer surface of said sealed insulation panels, said valve stopper default status being closed; and
a suction interface located in the proximity of said evacuation orifice,
said suction interface being adapted to be connected to a source of vacuum suction.

63. The vacuum valve of claim 62, wherein said suction interface being further adapted to be connected to an adaptor of said source of vacuum suction.

64. The sealed insulation panel of claim 62, wherein said vacuum valve being positioned within a spout, said spout being adapted to overlie an evacuation aperture in a sealed insulation panels, said spout substantially forming a tube with an open first end and an open second end.

65. The sealed insulation panel of claim 62, wherein said vacuum valve comprises:
a spring recess located in said sink shaped chamber;
a spring adapted to be threaded on said recess, pressing said valve stopper toward said evacuation orifice, said spring being adapted to maintain said vacuum valve closed when released or open when pressed by said valve stopper.

66. A method of producing sealed vacuum thermal insulation panels having a vacuum valve, comprising the following steps:
a) providing a sealed insulation panel of film substantially impermeable to atmospheric gases and water vapor, the panel having an aperture;
b) providing a permanent vacuum valve having a valve stopper, said permanent vacuum valve adapted to overlie said aperture, said permanent vacuum valve having a suction interface, said suction interface adapted to be connected to a source of vacuum suction;
c) positioning said permanent vacuum valve in said aperture;
d) connecting a source of vacuum suction to said suction interface; and
e) evacuating said sealed insulation panel using said source of vacuum suction.

67. A vacuum pump adaptor for suction transfer between permanent vacuum valves of sealed insulation panels and suction apparatus, comprising:
a readily removable pedestal having a bottom duct for sealably connecting a permanent vacuum valve and a top outlet for sealably connecting a suction apparatus;
a pivot screwed through said readily removable pedestal, having a rotating handle operable for facilitating the screwing or the unscrewing of the pivot, said pivot being operable for retaining said vacuum valve open during the suction transfer.

68. The vacuum pump adaptor of claim 67, wherein said bottom duct is coupled to an O-ring operable for retaining the pressure level within said vacuum pump during said suction transfer when bottom conduit is coupled to said permanent vacuum valve.

69. The vacuum pump adaptor of claim 67, wherein said top outlet is a conduit with a right-angle bend, sealably coupled to said pedestal in a manner that facilitates the rotation of said top outlet orifice direction around the horizontal axis.

70. The vacuum pump adaptor of any of claims 67-69, wherein said readily removable pedestal being adapted to be permanently positioned between a vacuum thermal insulation panel and a protection film;
wherein said pivot is readily removable, said pivot further comprises an integrated tube having one end for connection to said vacuum valve and another end for connection to a source of vacuum suction;
wherein said vacuum valve said top outlet being adapted to be connected to said pivot is readily removable.

71. A replacement device for replacing getters and desiccating agents in a vacuum sealed panel, comprising:
a sink shaped chamber adapted to be positioned to overlie an aperture in the sealing of said vacuum sealed panel, having at least one gas-permeable wall and an aperture, said sink shaped chamber being operative for holding getters and desiccating agents; and
a cover of material substantially impermeable to atmospheric gases and water vapor, said cover designed to sealably overlie said aperture, being proximately positioned at the external side of said vacuum sealed panel.

72. The replacement device of claim 71, wherein said cover is a removable cover.

73. The replacement device of claim 71, wherein said cover is a permanent cover.

74. The replacement device of claim 71, wherein said sink shaped chamber further comprises:
a suction interface provided in said sink shaped chamber, said suction interface one end connection that matches said aperture and another end connection that matches a source of vacuum suction.

75. The replacement device of claim 71, wherein said sink shaped chamber further comprises an O-ring positioned in a groove in the internal walls of said sink shaped chamber, said O-ring being adapted to seal the junction between said sink shaped chamber and said cover.

76. A method of producing sealed vacuum thermal insulation panels having a housing for getters and desiccating agents, comprising the following steps:
a) providing a sealed insulation panel of film substantially impermeable to atmospheric gases and water vapors, the panel having an aperture and a vacuum valve;
b) providing a replacement device overlaying said aperture, said replacement device comprises a sink shaped chamber with at least one gas-preamble wall and a cover being substantially impermeable to atmospheric gases and water vapor, arranged to overlie the orifice of said sink shaped chamber;
c) positioning said replacement device in said aperture;
d) connecting said vacuum valve to a source of vacuum suction;
e) evacuating said sealed insulation panel using said source of vacuum suction;
f) inserting at least one absorbent agent to said sink shaped chamber; and
g) closing said aperture using said cover.

77. The method for producing sealed vacuum thermal insulation panels of claim 76, further comprising a step of g) removing said cover and repeating steps d-g.

78. The method for producing sealed vacuum thermal insulation panels of claim 76, further comprising a step between step b) and c) of positioning a filling in said sink shaped chamber to fill the internal space of said sink shaped chamber; and further comprising a step between step e) and f) of removing said filling.

79. A method for coupling partition films to insulation panels in insulation units, comprising the following steps:
a) providing at least one thermal insulation panel having an obverse side and a reverse side and at least one partition film;
b) laminating a first layer of thermally activated adhesive on said obverse side of said thermal insulation panel;
c) coupling said reverse side of said thermal insulation panel to the inner side wall of a insulation unit;
d) sealably positioning said partition at the proximity of said thermal insulation panel at room temperature;
e) transmitting an activation radiation on the resultant arrangement of said positioning to thereby activate said first layer of thermally activated adhesive, gluing said obverse said of said thermal insulation panel with said partition film.

80. The method of claim 79, said activation radiation is RF radiation.

81. The method of claim 79, further comprising a step between step b) and c) of laminating a second layer of thermally activated adhesive on said reverse side of said thermal insulation panel; further comprising a step e) of transmitting activation radiation on the resultant arrangement of said positioning to thereby activate said second layer of thermally activated adhesive, gluing the reverse side of said thermal insulation panel to the inner side wall of a insulation unit.

82. A vacuum thermal isolating panel, comprising a thermal isolating porous material packed in a sealed bag, the bag having a plurality of substantially impermeable metallic films being welded via a sealing layer, wherein said plurality of metallic films are arranged such as to have oxygen transmission rate of less than 0.005 (cc mm/m² day ATM) at 55 degrees centigrade.

83. A vacuum thermal isolating panel, comprising a thermal isolating porous material packed in a sealed bag, the bag having at least one substantially impermeable film having therein at least one metallic layer other than aluminum.

84. A vacuum thermal isolating panel, comprising a thermal isolating porous material packed in a sealed bag, the bag having at least one substantially impermeable metallized film having at least one layer of Polyethylene Naphthalate therein.

85. A vacuum thermal isolating panel, comprising a thermal isolating porous material packed in a sealed bag the bag having at least one substantially impermeable metallized film having at least one layer of polyvinyl alcohol therein.

86. A vacuum thermal isolating panel, comprising a thermal isolating porous material packed in a sealed bag, the bag having at least one substantially impermeable metallized film having at least one layer of cycloolefin copolymer therein.
